(19) United States
(12) Patent Application Publication
(10) Pub. No.: US 2007/0290708 A1
(43) Pub. Date: Dec. 20, 2007

(54) INSPECTION SYSTEM AND INSPECTION CIRCUIT THEREOF, SEMICONDUCTOR DEVICE, DISPLAY DEVICE, AND METHOD OF INSPECTING SEMICONDUCTOR DEVICE

(75) Inventor: KENICHI TAKATORI, Tokyo (JP)

Correspondence Address: DICKSTEIN SHAPIRO LLP, 1177 AVENUE OF THE AMERICAS (6TH AVENUE), NEW YORK, NY, 10036-2714, US

(73) Assignees: NEC CORPORATION, Tokyo (JP); NEC LCD Technologies, Ltd., Kanagawa (JP)

(21) Appl. No.: 11/761,873

(22) Filed: Jun. 12, 2007

(30) Foreign Application Priority Data
Jun. 14, 2006 (JP) 2006-0164139

(51) Int. Cl. G01R 31/26

(52) U.S. Cl. 324/765

(57) ABSTRACT

The present invention provides an inspection system with small increase in circuit area and capable of controlling increase in cost to be small. An inspection circuit intervenes between a first circuit and a second circuit. Further, the inspection circuit includes a signaling control portion and an inspection output portion. The signaling control portion controls signaling between the first circuit and the second circuit. Moreover, the inspection output portion outputs an output of the first circuit for inspection through the inspection circuit. In the present invention, the signaling control portion and the inspection output portion share a part of the circuit to realize their own function. Further, the first circuit, the second circuit and the inspection circuit are formed on the same substrate. The inspection circuit switches between the signaling control portion and the inspection output portion to use.

### BACKGROUND OF THE INVENTION

1. Field of the Invention

The present invention relates to an inspection system and an inspection circuit thereof, a semiconductor device, a display device, and a method of inspecting a semiconductor device, and more particularly, to an inspection circuit incorporated in a display device or a semiconductor device.

2. Description of the Prior Art

As technologies have been developed recently, a display device is made to fit for practical use, which incorporates, on a support substrate, various circuits such as a drive circuit which have been provided externally by using a LSI (Large Scale Integrated circuit) etc. conventionally formed by the silicon technology. An example of such a display device with a built-in circuit is a well-known display device formed by a high temperature polysilicon TFT (Thin Film Transistor) technology according to a high temperature process using an expensive quartz substrate. Further, a display device which has a circuit embedded on a glass substrate etc. is also turned into practical use by using a low temperature polysilicon technology in which a precursor film is formed in a low temperature process and annealed by a laser etc. to polycrystallize.

For a specific example, an active matrix display device is disclosed in Patent Document 1 (Japanese Patent Laid-Open No. 2004-046054 (FIGS. 37 and 38)). FIG. 36 is a schematic view illustrating a configuration of an example of a display system in a conventional, typical liquid crystal display device integrated with a drive circuit shown in FIG. 37 of Patent Document 1.

Referring to FIG. 36, the conventional liquid crystal display device including a drive circuit in a body providing an active matrix display area 110 in which pixels are arranged in M rows and N columns and wired therebetween in matrix, a scanning circuit in the row direction 109 (scanning line (gate line) drive circuit), a scanning circuit in the column direction 3504 (data line drive circuit), an analog switch 3505, a level shifter 3503 etc. on a display device substrate 101 by a polysilicon TFT.

As a controller IC (Integrated Circuit) 102, an integrated circuit chip (IC chip) which has a controller 113, a memory 111, a digital-to-analog conversion circuit (DAC: Digital to Analog Converter) 3502, a scanning circuit/data register 3501 etc. formed on a wafer of single-crystal silicon 102 is provided outside the display device substrate 101. Further, an interface circuit 114 is formed on a circuit substrate 103 on the system side and connected to the controller 113 and the memory 111.

Further, there is a device in which more complex circuits such as a DAC circuit are formed in a body in the conventional liquid crystal display device including a drive circuit in a body configured by using a polysilicon TFT. FIG. 37 shows a schematic view illustrating a configuration of an example of a display system in a conventional liquid crystal display device including a drive circuit in a body incorporating a DAC circuit described in FIG. 38 of Patent Document 1.

The conventional liquid crystal display device including a drive circuit in a body incorporating a DAC circuit, similarly to the device without a DAC circuit therein shown in FIG. 36, provides an active matrix display area 110 in which pixels are arranged in M rows and N columns and wired therebetween in matrix, a scanning circuit in the row direction 109, and a scanning circuit in the column direction 3506, and in addition to them, a data register 3507, a latch circuit 105, a DAC circuit 106, a selector circuit 107, and a level shifter (D bits) 108 etc. formed in a body on a display device substrate 101.

A controller IC 102, which is provided outside the display device substrate 101 of this liquid crystal display device including a drive circuit in a body incorporating a DAC circuit, does not include a DAC circuit 3502 using a high voltage, so that the controller IC 102 can be configured of a memory 111, an output buffer circuit 112 and a controller 113 all of which are low voltage circuits and elements. As a result, because the controller 102 can be manufactured without using together a process for high voltage required to create a voltage signal to write into a liquid crystal display, its cost can be controlled less than that of the controller IC 102 providing the DAC circuit 3502 different from the other elements described above.

FIG. 38 is a schematic view illustrating a configuration of an example of a frame memory formed on a conventional glass substrate. FIG. 39 is a circuit diagram of an example of a memory cell providing a sense amplifier corresponding to a 1-bit line, which is used as a frame memory formed on a conventional glass substrate.

On the one hand, the inventors have gone ahead with integration of various circuits on a support substrate, and have applied a configuration for integrating a memory on a support substrate and its drive method for a patent (see Patent Document 2 (Japanese Patent Laid-Open No. 2006-115484)).

Moreover, a display data RAM 17 corresponding to a first circuit of the present invention and a liquid crystal drive circuit 20 corresponding to a second circuit of the present invention are disclosed in Patent Document 3 (Japanese Patent Laid-Open No. 2002-197899 (FIG. 1)). It is also disclosed in Patent Document 3 that a test mode signal (reset signal) is input into a control circuit 11 of a MPU system through a MPU interface 12.

Further, a BIST circuit corresponding to an inspection circuit of the present invention, a data output latch 3 corresponding to an inspection output portion 5 of the present invention and a data input latch 2 corresponding to an inspection input portion 6 of the present invention are disclosed in Patent Document 4 (Japanese Patent Laid-Open No. 2005-129174 (FIG. 1)).

### BRIEF SUMMARY OF THE INVENTION

However, in the conventional technology described above and the liquid crystal display device integrated with a drive circuit described in Patent Document 1, display data for all pixels is transferred to a liquid crystal module for each frame at a high rate in serial format. Therefore, the finer an image is and the larger the number of pixel is, the larger the transfer rate becomes. As the result of transfer at a high rate, a driver IC (integrated circuit) is also required for higher transfer rate operation, and accordingly through current etc. may be produced in a number of CMOSs (complementary metal oxide semiconductor) constituting a circuit element. Then, electric power consumption is increased due to increase in operation speed. Further, a cost of a high-speed IC is increased. Moreover, the more a number of gradation increases, the more a circuit configuration is complex and the more : a transfer rate further increases, resulting in further more power consumption and a larger cost. That is, higher-definition and higher-gradation display causes a cost and power consumption of the driver IC to be increased, which presents a problem that the number of pixel and the number of gradation are limited because the increase on power consumption and a cost of the entire system are to be suppressed.

Further, voltage used for each of circuit blocks on the display device substrate 101 (see FIGS. 36 and 37) is different from each other, and therefore processes corresponding to a plurality of voltages have to be used together, also resulting in a problem of a higher cost of manufacturing process.

Moreover, in this liquid crystal display device integrated with a drive circuit, the controller IC 102 and an interface IC 114 (see FIGS. 36 and 37) are provided outside the display device substrate, also presenting a problem that a display device cannot be miniaturized.

Further, according to the invention disclosed in Patent Document 2 described above, in a circuit in which a MOS (metal oxide semiconductor) transistor having a SOI (silicon on insulator) configuration with a polysilicon TFT etc. is integrated, a bad operation due to the history effect can be controlled, and sensitivity of a latch-type sense amplifier circuit and a latch circuit including such a MOS transistor as a component thereof can be improved.

As described above, the invention disclosed in Patent Document 2 has achieved the initial object, but, in the case of a configuration in which a memory is integrated on a support substrate, inspection environment similar to that for a conventional LSI has not been developed, and therefore it is difficult to inspect a memory portion. Accordingly, it is difficult to discriminate a good item which operates well. Then, determination whether it is good or bad can be made only after a display device with the memory portion mounted therein is finished. Further, because a drive circuit portion is not separated, for example, into a display portion and a drive IC, it is difficult to determine whether a bad portion is present in the display portion or in the drive circuit portion including the memory when a display failure etc. occurs. Therefore, whether a problem concerning design or manufacturing is present in the display portion or in the drive circuit portion including the memory may be unknown, making it difficult to solve the problem to improve.

To facilitate this inspection or analysis, it is considered that a circuit for inspecting a memory portion formed on a support substrate is formed on the support substrate. An inspection circuit for inspecting data stored in the memory portion is preferably provided in an output portion of the memory. Further, to verify the data stored, a configuration in which all data stored in the memory may be read out is preferable.

It is considered that a configuration using a memory inspection circuit having such a configuration may be, for example, a configuration shown in FIG. 40. As shown in FIG. 40, an output of a memory 111 is temporally held in an output register 130. An output of this output register 130 passes through an inspection circuit 131 without changing a data state at the time of normal operation. The data which passed through the inspection circuit 131 is transferred to a display area 110 by a drive circuit incorporating a DAC 132. On the one hand, the output of the output register 130 is output for inspection through the inspection circuit 131 on inspection.

FIG. 41 shows an example of a circuit for the output register 130 and the inspection circuit 131 shown in the schematic view of the configuration of FIG. 40. The output register 130 includes, for example, a latch circuit. The output of this output register 130 passes through the inspection circuit 131 to connect to the drive circuit incorporating a DAC side. Further, the output of the output register 130 branches to enter a buffer 133 in the inspection circuit 131. An output of the buffer 133 is input into one of ends of a selector 135. The other end of the selector 135 is connected to an inspection output line 134. The selector 135 is switched by a shift register 136. In the example shown in FIG. 41, each 4-bit data is selected by the shift register 136 and output into 4-bit inspection output line 134.

However, when this inspection circuit is used, not only an output register used in a conventional configuration in which a memory is integrated, but a shift register for reading out inspection data is used. Further, a readout line of data has to be extended long and load such as parasitic capacitance on the data readout line is increased, and therefore rising of a data signal read out becomes slow. To improve the slow rising of the data signal, it is necessary to make a buffer for readout larger.

Further, a buffer is required in each of outputs of circuits to be inspected, which is capable of driving the data readout line entirely, and therefore the buffer is enlarged. As the result, a circuit area is enlarged extremely by addition of the inspection circuit. In addition, because of a large area of the inspection circuit, a wiring length between a memory portion and a display portion is made long and further parasite capacitance etc. is increased. As a result, also a problem arises that a data transfer rate between the memory portion and the display portion is decreased.

On the other hand, when the inspection circuit is removed from the configuration as shown in FIG. 40, it is difficult to judge whether an object of the inspection fills the specification or not, besides it is difficult to specify a bad portion as described above. As a result, a cost of inspection increases extremely.

Further, the inventions disclosed in Patent Documents 3 and 4 do not absolutely disclose a configuration in which the inspection circuit is provided between the first circuit and the second circuit.

Therefore, an object of the present invention is to provide an inspection system with small increase in circuit area and capable of controlling increase in cost to be small, and its inspection circuit, semiconductor device and display device, as well as a method of inspecting a semiconductor device.

An inspection circuit according to the present invention is the inspection circuit intervening between a first circuit and a second circuit, wherein the inspection circuit includes a signaling control portion of controlling signaling between the first circuit and the second circuit and an inspection output portion of inspecting at least one of the first circuit and the second circuit, and switches between the signaling control portion and the inspection output portion to use, and each portion shares a part of the circuit to realize each portion with each other.

Further, an inspection system according to the present invention includes the inspection circuit.

Further, a semiconductor device according to the present invention includes the inspection circuit.

Further, a display device according to the present invention may include a display portion to realize display function in the semiconductor device.

Further, a method of inspecting a semiconductor device is the method of inspecting a semiconductor device which transmits signals from a first circuit to a second circuit by using a signaling circuit intervening between the first circuit and the second circuit, wherein inspecting an output of the first circuit by bringing the signaling between the first circuit and the second circuit to a halt and connecting an output of an output portion of the first circuit to an inspection output circuit which shares a part of a circuit with the signaling circuit.

Further, another inspection system according to the present invention is the inspection system which includes a first circuit, a second circuit and an inspection circuit intervening between the first circuit and the second circuit, wherein the inspection circuit includes a signaling control means of controlling signaling between the first circuit and the second circuit and an inspection output means of inspecting at least one of the first circuit and the second circuit, and switches between the signaling control means and the inspection output means to use, and each of the means shares a part of a circuit to realize each means with each other.

Next, operation of the present invention will be described. An inspection circuit of the present invention includes a plurality of functions and each of the functions shares a part of the circuit to realize their own function, so that a size of the circuit to realize the plurality of functions may be reduced. Further, a part of a signaling control circuit and the inspection circuit is shared, and therefore a size of the circuit may be reduced extremely. Also, because a length of a data readout line is shortened, then parasitic capacitance is decreased, resulting in a smaller size of a buffer. Further, because it is not necessary to drive entirely the data readout lines, the buffer size is reduced. Accordingly, a circuit area may be decreased extremely, resulting in a low cost of inspection.

On the one hand, because a pattern compression circuit, a pattern generator circuit or BIST (built-in self test) is built in the inspection circuit, the number of pin in the inspection device can be decreased and/or the number of element to be inspected at the same time can be increased. Further, due to a lower performance required for the inspection device, a cost of inspection can be extremely reduced.

The present invention may provide an inspection system with small increase in circuit area and capable of controlling increase in cost to be small, and its inspection circuit, a semiconductor device and a display device, as well as a method of inspecting a semiconductor device.

Now, examples of the present invention will be described with reference to the accompanying drawings.

### BRIEF DESCRIPTION OF THE DRAWINGS

FIG. 1 is a schematic view illustrating a configuration of a first example of an inspection system according to the present invention;

FIG. 2 is a schematic view illustrating another example of a functional block of an inspection circuit of the first example;

FIG. 3 is a schematic view illustrating a configuration of a second example of an inspection system according to the present invention;

FIG. 4 is a schematic view illustrating a configuration of a third example of an inspection system according to the present invention;

FIG. 5 is a schematic view illustrating a configuration and operation of a fourth example of an inspection system according to the present invention;

FIG. 6 is a schematic view illustrating a configuration and operation of the fourth example of an inspection system according to the present invention;

FIG. 7 is a schematic view illustrating a configuration and operation of the fourth example of an inspection system according to the present invention;

FIG. 8 is a circuit diagram for an example in which a D flip-flop is used as a flip-flop;

FIG. 9 is a circuit diagram for an example in which a D flip-flop is used as a flip-flop;

FIG. 10 is a circuit diagram for an example of a shift register latch;

FIG. 11 is a circuit diagram for an example in which a transfer gate and an inverter are used as an internal circuit of a D flip-flop;

FIG. 12 is a circuit diagram for an example of a non-overlapping clock;

FIG. 13 is a circuit diagram for an example in which a clocked inverter and an inverter are used as a D flip-flop;

FIG. 14 is a circuit diagram for an example in which a TSPC is used as a D flip-flop;

FIG. 15 is a circuit diagram for an example in which a sense amplifier is used as a D flip-flop;

FIG. 16 is a schematic view illustrating a configuration of a fifth example of an inspection system according to the present invention;

FIG. 17 is a schematic view illustrating a configuration of a sixth example of an inspection system according to the present invention;

FIG. 18 is a schematic view illustrating a configuration of a seventh example of an inspection system according to the present invention;

FIG. 19 is a schematic view illustrating a configuration of an eighth example of an inspection system according to the present invention;

FIG. 20 is a schematic view illustrating a configuration of a ninth example of an inspection system according to the present invention;

FIG. 21 is a schematic view illustrating a configuration of a tenth example of an inspection system according to the present invention;

FIG. 22 is a schematic view illustrating a configuration of an eleventh example of an inspection system according to the present invention;

FIG. 23 is a schematic view illustrating a configuration of a twelfth example of an inspection system according to the present invention;

FIG. 24 is a schematic view illustrating a configuration of a thirteenth example of an inspection system according to the present invention;

FIG. 25 is a schematic view illustrating a configuration in which an inspection circuit is disposed one-by-one between each of circuits;

FIG. 26 is a schematic view illustrating a configuration of a fourteenth example of an inspection system according to the present invention;

FIG. 27 is a circuit diagram for an example of an output register-cum-inspection circuit 140;

FIG. 28 is a schematic view illustrating a configuration of a fifteenth example of an inspection system according to the present invention;

FIG. 29 is a schematic view illustrating a configuration of a sixteenth example of an inspection system according to the present invention;

FIG. 30 is a schematic view illustrating a configuration of an example of a memory BIST;

FIG. 31 is a schematic view illustrating a configuration of an example of a BIST circuit of a nineteenth example;

FIG. 32 is a circuit diagram for an example of a clocked comparator;

FIG. 33 is a circuit diagram for an example of a clocked comparator;

FIG. 34 is a schematic view illustrating a configuration of an example of a circuit on a TFT substrate;

FIG. 35 is a schematic view illustrating an example of a timing chart of this example;

FIG. 36 is a schematic view illustrating a configuration of an example of a display system in a conventional, usual liquid crystal display device integrated with a drive circuit described in FIG. 37 of Patent Document 1;

FIG. 37 is a schematic view illustrating a configuration of an example of a display system in a conventional liquid crystal display device integrated with a drive circuit incorporating a DAC circuit described in FIG. 38 of Patent Document 1;

FIG. 38 is a schematic view illustrating a configuration of an example of a frame memory formed on a conventional glass substrate;

FIG. 39 is a circuit diagram for an example of a memory cell having a sense amplifier corresponding to a 1-bit line used for a frame memory formed on a conventional glass substrate;

FIG. 40 is a schematic view illustrating a configuration of an example of a conventional memory inspection circuit; and

FIG. 41 is a schematic view illustrating an example of a circuit of an output register 130 and an inspection circuit 131 in the configuration shown in FIG. 40.

### DETAILED DESCRIPTION OF THE PREFERRED EMBODIMENTS

### EXAMPLE 1

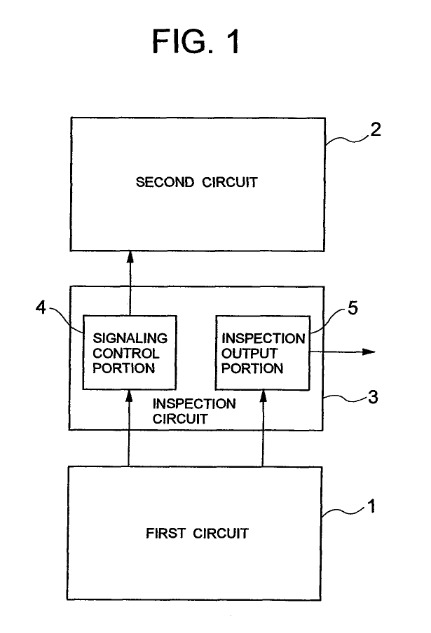

FIG. 1 is a schematic view illustrating a configuration of a first example of an inspection system according to the present invention. Referring to FIG. 1, the first example of the inspection system according to the present invention includes a first circuit 1, a second circuit 2 and an inspection circuit 3.

The inspection circuit 3 intervenes between the first circuit 1 and the second circuit 2. Further, the inspection circuit 3 includes a signaling control portion 4 and an inspection output portion 5. The signaling control portion 4 controls signaling between the first circuit 1 and the second circuit 2. Further, the inspection output portion 5 outputs an output of the first circuit 1 for inspection through the inspection circuit 3. According to the present invention, the signaling control portion 4 and the inspection output portion 5 share a part of the circuit to realize their own function with each other. Further, the first circuit 1, the second circuit 2 and the inspection circuit 3 are provided on the same substrate.

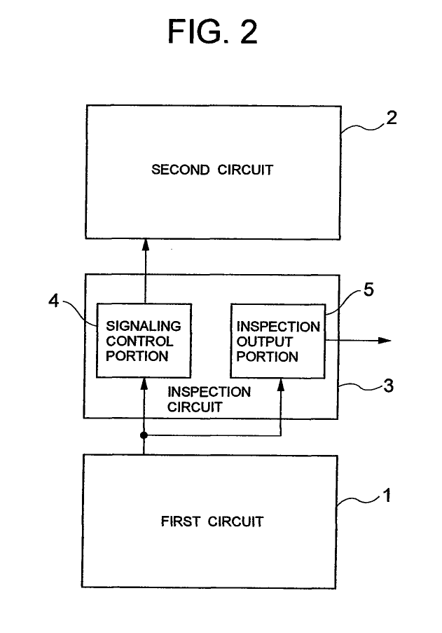

FIG. 2 is a schematic view illustrating another example of a functional block of the inspection circuit of the first example. A different point from FIG. 1 is that an input from the first circuit 1 is input into each function in the inspection circuit 3 by making an output of the first circuit 1 branch. In the first example, the signaling control portion 4 and the inspection output portion 5 share a part of the circuit to realize their own function with each other.

When a circuit corresponding to an interface portion (not shown) with the first circuit 1 is shared, as shown in FIG. 2, the input from the first circuit 1 is input into each of functions in the inspection circuit 3 by making the output of the first circuit 1 branch.

In the present invention, the signaling control portion 4 and the inspection output portion 5 share a part of the circuit to realize their own function with each other, and therefore the entire circuit size is reduced. As a result, increase in circuit area due to providing the inspection circuit may be controlled to be small, resulting in a smaller area of the entire chip. Further, because of the smaller size of the circuit, a probability of failure occurrence is reduced. Further, owing to the decreased chip area and the reduced probability of failure occurrence, a cost of the entire system is reduced. Also, the inspection circuit may be provided in addition to the first and the second circuits in the present invention, resulting in a low cost of inspection.

### EXAMPLE 2

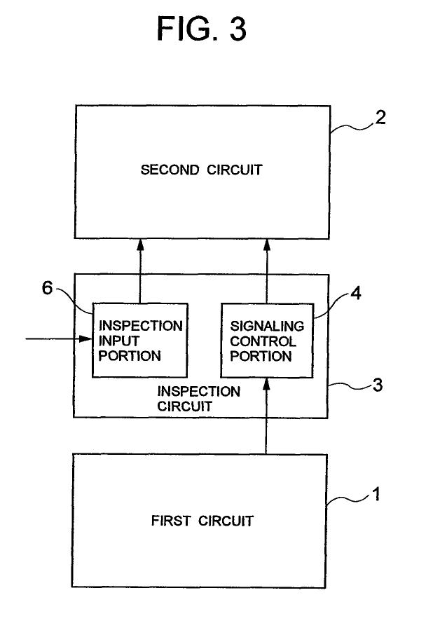

FIG. 3 is a schematic view illustrating a configuration of a second example of an inspection system according to the present invention. Referring to FIG. 3, the second example of the inspection system according to the present invention includes a first circuit 1, a second circuit 2 and an inspection circuit 3.

The inspection circuit 3 intervenes between the first circuit 1 and the second circuit 2. Further, the inspection circuit 3 includes a signaling control portion 4 and an inspection input portion 6. The signaling control portion 4 controls signaling between the first circuit 1 and the second circuit 2. Further, the inspection input portion 6 outputs an inspection signal to be input externally, to the second circuit 2 through the inspection circuit 3. In the present invention, the signaling control portion 4 and the inspection input portion 6 share a part of the circuit to realize their own function with each other. Further, the first circuit 1, the second circuit 2 and the inspection circuit 3 are provided on the same substrate.

In the present invention, the signaling control portion 4 and the inspection input portion 6 share a part of the circuit to realize their own function with each other, and therefore the entire circuit size is reduced. As a result, increase in circuit area due to providing the inspection circuit may be controlled to be small, resulting in a smaller area of the entire chip. Further, because of the smaller size of the circuit, a probability of failure occurrence is reduced. Further, the chip area is decreased and the probability of failure occurrence is reduced, resulting in a low cost of the entire system. Also, the inspection circuit may be provided in addition to the first and the second circuits in the present invention, resulting in a low cost of inspection.

### EXAMPLE 3

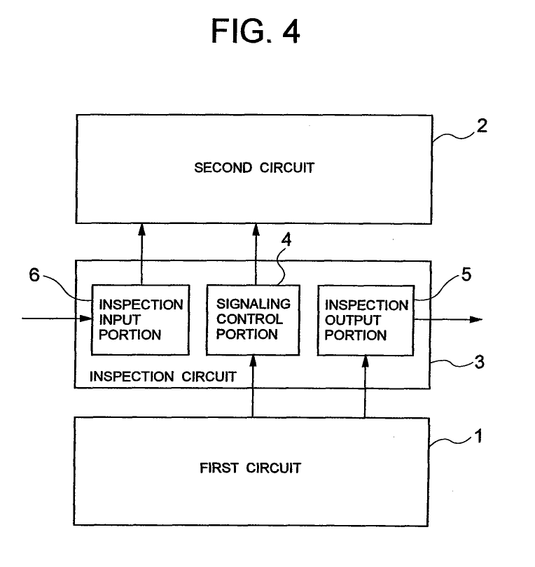

FIG. 4 is a schematic view illustrating a configuration of a third example of an inspection system according to the present invention. Referring to FIG. 4, the third example of the inspection system according to the present invention includes a first circuit 1, a second circuit 2 and an inspection circuit 3.

The inspection circuit 3 of the present invention intervenes between the first circuit 1 and the second circuit 2. Further, the inspection circuit 3 includes a signaling control portion 4, an inspection output portion 5 and an inspection input portion 6. The signaling control portion 4 controls signaling between the first circuit 1 and the second circuit 2. Further, the inspection output portion 5 outputs an output of the first circuit 1 for inspection through the inspection circuit 3. Further, the inspection input portion 6 outputs an inspection signal to be input externally, to the second circuit 2 through the inspection circuit 3. In the present invention, the signaling control portion 4, the inspection output portion 5 and the inspection input portion 6 share a part of the circuit to realize their own function with each other. Further, the first circuit 1, the second circuit 2 and the inspection circuit 3 are provided on the same substrate.

In the present invention, the signaling control portion 4, the inspection output portion 5 and the inspection input portion 6 share a part of the circuit to realize their own function with each other, and therefore the entire circuit size is reduced. As a result, increase in circuit area due to providing the inspection circuit may be controlled to be small, resulting in a smaller area of the entire chip. Further, because of the smaller size of the circuit, a probability of failure occurrence is reduced. Further, the chip area is decreased and the probability of failure occurrence is reduced, resulting in a low cost of the entire. Also, the inspection circuit may be provided in addition to the first and the second circuits in the present invention, resulting in a low cost of inspection.

Further, in the present invention, inspection of an output of the first circuit and data inputting for inspection of the second circuit can be carried out by the same inspection circuit 3. That is, the two inspection functions and the signaling function between circuits can be carried out by one inspection circuit. As a result, a cost can be largely suppressed and a higher-reliability circuit can be realized.

### EXAMPLE 4

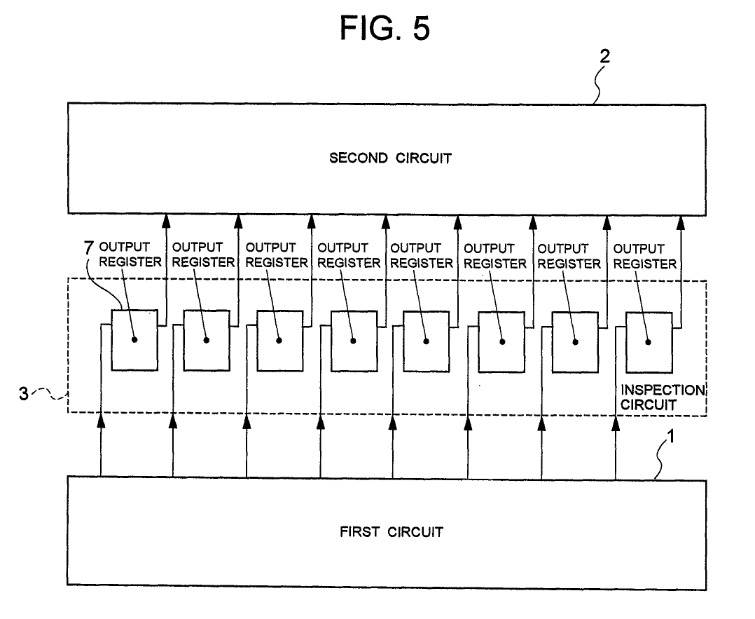

FIGS. 5 to 7 are schematic views illustrating a configuration and operation of a fourth example of an inspection system according to the present invention. As described above, to realize the signaling control portion 4 for controlling signaling between the first circuit 1 and the second circuit 2, for example, a signaling control circuit portion of an output register (output buffer) etc. composed of a latch etc. is required.

On the one hand, for example, when an output of the first circuit 1 is a parallel output and this output with a plurality of bits is inspected, inspection may be easily performed by converting data in a shift register etc. into serial data format using a circuit which transfers data in series. A specific circuit configuration for the inspection circuit 3 of the present invention uses a circuit capable of performing both of the function of an output register and the function of a shift register.

That is, in the inspection circuit of the fourth example of the present invention, the shared circuit includes a latch circuit. This latch circuit functions, at the time of normal operation, as an output register (buffer) 7 (see FIG. 5) provided between the first circuit 1 and the second circuit 2.

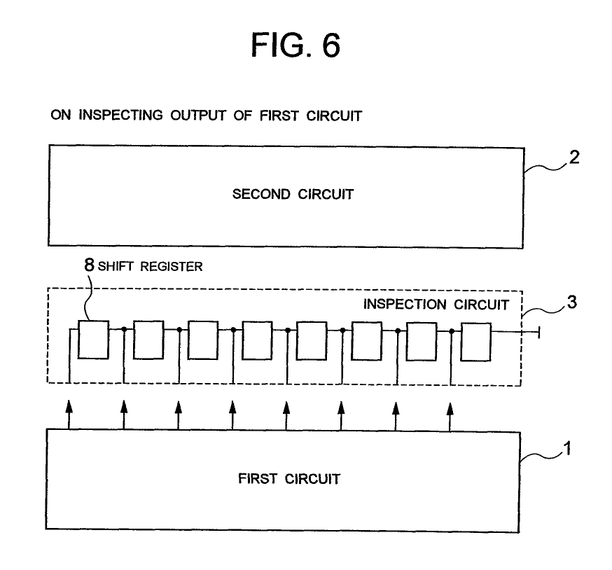

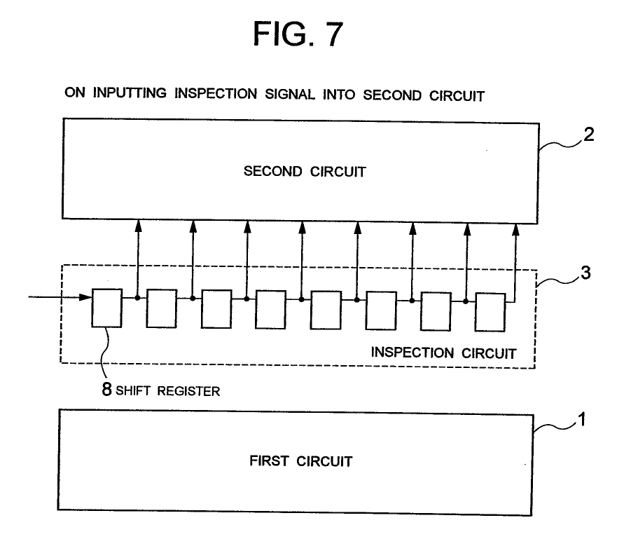

On the one hand, on inspection, the latch circuit works as a shift register 8 or constitutes the shift register 8 (see FIG. 6 or FIG. 7). This shift register 8 can be used not only for outputting for inspection (see FIG. 6), but for inputting for inspection (see FIG. 7). Conventionally, for both of the output register and the shift register, a plurality of flip-flops are necessary, but the configuration of the present invention may reduce the number of flip-flop to half.

For example, when one output register is formed by connecting 500 flip-flops composed of 12 transistors, the number of only transistor in the flip-flops in a conventional inspection circuit portion is computed to be 12×500×2=12,000. According to the present invention, this number is only 6,000.

FIGS. 5 to 7 illustrate an example of a signal flow at each operational mode of this example. FIG. 5 illustrates the signal flow at the time of normal operation. FIG. 6 illustrates it on inspecting the output of the first circuit 1. FIG. 7 illustrates it on inputting the inspection signal into the second circuit 2. At the time of normal operation of FIG. 5, the parallel output of the first circuit 1 is held temporarily by the output register 7 in the inspection circuit 3 and then it is transferred to the second circuit 2.

When the parallel output of the first circuit 1 is inspected, first, in the configuration shown in FIG. 5, the output of the first circuit 1 is held temporarily by the output register 7 in the inspection circuit 3. Next, the configuration is adapted as shown in FIG. 6. That is, the output register 7 and the first circuit 1 are disconnected. Further, connection between the output register 7 is changed to form the shift registers 8. This allows the output of the first circuit 1 held by the output register 7 to be read out externally in series as serial data format from the shift register 8.

In addition, in FIG. 6, the shift register 8 is not connected to the second circuit 2, but even if they are connected to each other, inspection function of the output of the first circuit 1 can be similarly performed by using the shift register 8.

On the one hand, when the inspection signal in form of serial data is input into the second circuit 2, connection is adapted as shown in FIG. 7. Here, the output register 7 at normal operation is connected to form the shift register 8. Further, an output of each stage of the shift register 8 is connected to an input portion of the second circuit 2. According to this configuration, when the inspection signal is input externally, the inspection signal is transferred in series to the second circuit 2 due to the shift register 8. When a register is provided in the second circuit 2, the register holds the inspection input signal until the inspection signal is transferred up to all of desired input terminals of the second circuit 2, and after the inspection signal is transferred up to all of the desired input terminals of the second circuit 2, the second circuit 2 can be also inspected.

In addition, according to the present invention, when the inspection signal is input into the second circuit 2, this inspection input signal may be read out from the outputting side for inspection of the first circuit 1. For example, serial data as the inspection signal to the second circuit 2 is input from the left side in FIG. 7, and then the serial data may be read out from the right side in FIG. 6 for using the serial data as the inspection output of the first circuit 1. Using this function, the inspection input signal to be input from the left side in FIG. 7 and the inspection output signal obtained from the right side in FIG. 6 can be compared to inspect the inspection circuit itself to determine whether it operates normally or not.

Now, the shared circuit described above includes, for example, a flip-flop similar to the flip-flop used in a MUX scan (multiplexer scan) system which is a kind of scan-pass-test. That is, the flip-flop having a multiplexer in its input portion is used.

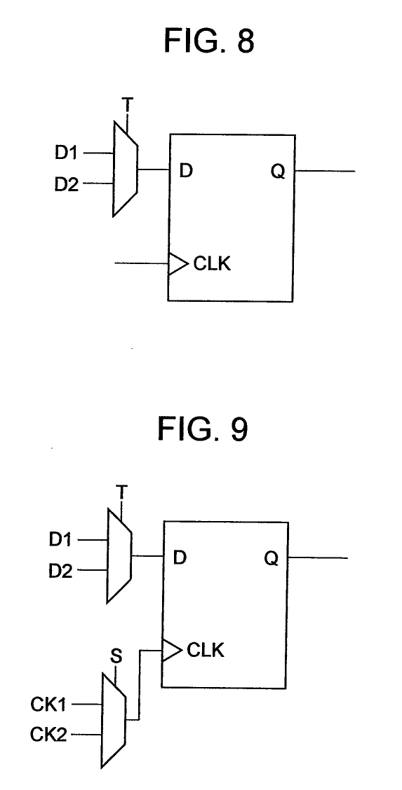

FIG. 8 illustrates an example in which a D flip-flop is used as the flip-flop. The multiplexer (MUX) is inserted before a D terminal which is an input of the D flip-flop. The multiplexer is controlled by a signal T, and either an input signal D1 or D2 is input into the D terminal. The signal input into the D terminal is controlled to be output to a Q terminal by a CLK signal.

In addition to the configuration shown in FIG. 8, the flip-flop in which the multiplexer is also added to a clock input is used. This is the same configuration as that of a two-port flip-flop. FIG. 9 illustrates an example in which a D flip-flop is used as the flip-flop, similarly to FIG. 8. The multiplexer is inserted before a D terminal which is an input of the D flip-flop and before a CLK terminal which is a clock input. The multiplexer of the D terminal is controlled by a signal T similarly to FIG. 8, and either an input signal D1 or D2 is input into the D terminal. On the one hand, the multiplexer of the CLK terminal is controlled by a signal S, and either a signal input CK1 or CK2 is input into the CLK terminal.

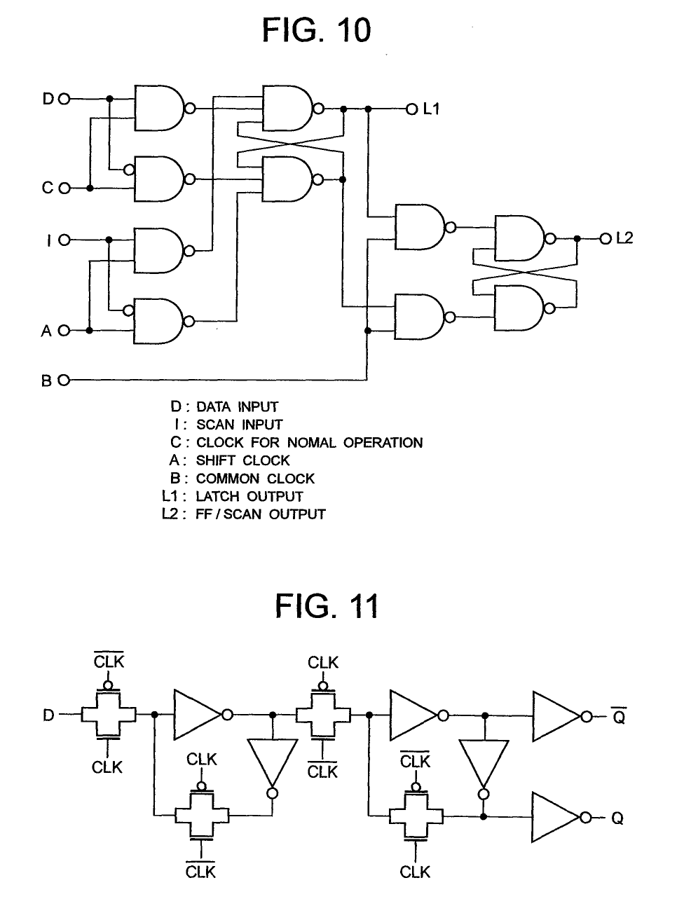

On the one hand, also it may be possible to use a shift register latch (which may be also called “Polarity Hold Latch”) which realizes the same function as described above without using the multiplexer. FIG. 10 illustrates this example. This shift register latch includes mainly a NAND circuit and partially an inverter (in FIG. 10, an inverter function is denoted by a small circle on one side of the NAND circuit to which a data input D or a scan input I is connected). In this configuration, three clocks, i.e. a clock C for normal operation, a shift clock A and a common clock B are used.

At the time of normal operation, the clock C for normal operation which is a non-overlapping clock and the common clock B are used, and the shift clock A is kept in L (a low state), and the data input D is latched. On inspection, the shift clock A which is a non-overlapping clock and the common clock B are used, and the clock A for normal operation is kept in L (a low state), and the scan input I is latched. This configuration does not include the multiplexer compared to FIG. 8 or FIG. 9. As a result, elimination of delay due to the multiplexer may allow speeding up.

In addition, an output of each stage of the flip-flop or the shift register latch may simply branch to connect to both of a next stage of the flip-flop or the shift register, and the second circuit 2 without using a switch etc., alternately it may be switchably connected to the second circuit 2 by using a switch etc.

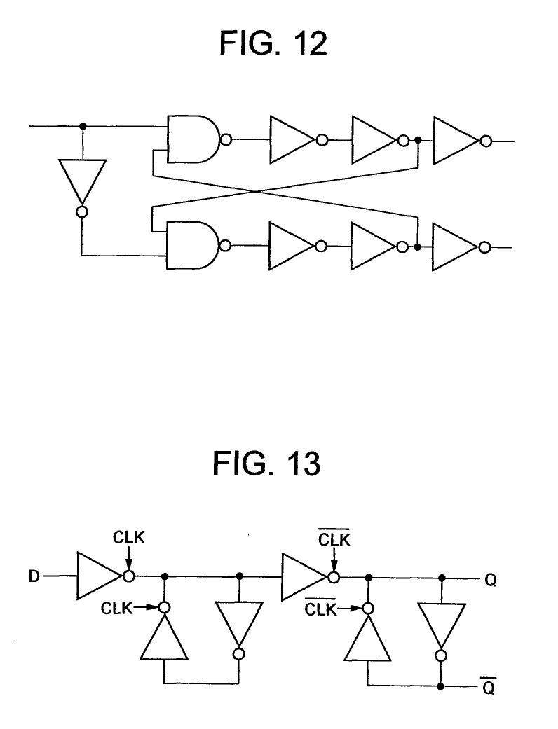

On the one hand, an internal circuit of the D flip-flop (the circuit of the D flip-flop itself excluding a multiplexer portion) may be configured by various methods. For example, it may be configured using a transfer gate and an inverter as shown in FIG. 11. This configuration requires two clocks, and it is necessary for these clocks to have a phase reversed to each other and for signals not to be overlapped with each other (that is, a so-called non-overlapping clock is necessary). Such a non-overlapping clock may be generated by, for example, a circuit composed of a NAND and an inverter as shown in FIG. 12.

The D flip-flop may be also configured by using a clocked inverter and an inverter, as shown in FIG. 13. This circuit, compared to the circuit in FIG. 11, may overcome the problem of clock skew more and operate even based on an overlapping clock. Thus, an additional circuit shown in FIG. 12 is not necessary, so that a circuit area can be reduced. However, when potential of the central node is varied, the variation passes on to an output to cause a large amount of current to flow between potentials of power supplies.

On the one hand, the D flip-flop composed of only a NAND may be also used. This circuit is comparatively stable and since an internal circuit is all the NAND circuit, design is easy.

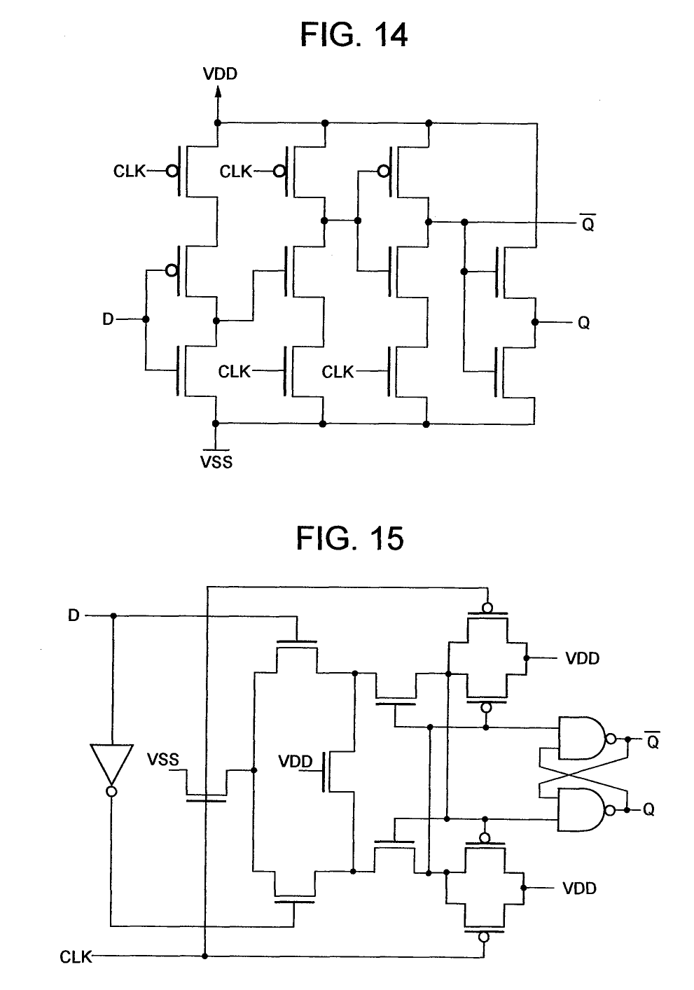

Alternately, a TSPC (true single phase clock or true single phase CMOS) shown in FIG. 14 may be also used as another D flip-flop. This circuit can operate at a high rate and only based on a single-phase clock, providing an advantage concerning a circuit area etc. However, this circuit is a mixed circuit having a static circuit and a dynamic circuit, and then when it is operated by a slow clock, a problem may arise.

On the one hand, the D flip-flop using a sense amplifier may be also used. The D flip-flop using the sense amplifier has been used in a CPU (central processing unit) called “StrongArm” and then it may be also called “StrongArm type”.

FIG. 15 is a circuit diagram of an example of the D flip-flop using the sense amplifier. The first stage is configured as the sense amplifier and the next stage is configured so that a NAND circuit is cross-coupled. This circuit may be operated by a single-phase clock, and therefore it is not affected by overlap or duty of the clock. Further, the number of transistor operated by the clock is as small as three, and then design concerning clock wiring may be also easy. Further, from our estimation, this D flip-flop can be used in a wide frequency range and operate even with a lowered supply voltage. Moreover, it is found that power consumption is low and this D flip-flop may be suitably used in the present invention.

### EXAMPLE 5

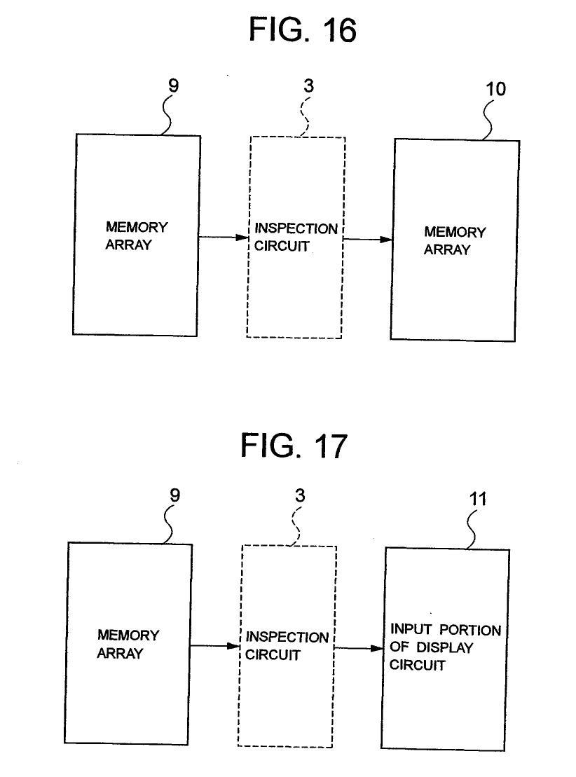

FIG. 16 is a schematic view illustrating a configuration of a fifth example of an inspection system according to the present invention. Referring to FIG. 16, the fifth example of the present invention is the device that the first circuit 1 is a memory array 9 and the second circuit 2 is also a memory array 10. This configuration is used when data is transferred between the memory arrays, alternately when data may be transferred from one of the memory arrays to the other of the memory arrays. According to the present invention, the inspection circuit 3 described above can inspect each of the memory arrays.

### EXAMPLE 6

FIG. 17 is a schematic view illustrating a configuration of a sixth example of an inspection system according to the present invention. Referring to FIG. 17, the sixth example of the present invention is the device that the first circuit 1 is a memory array 9 and the second circuit 2 is an input portion 11 of a display circuit. This configuration is used when data may be transferred from the memory array 9 to the input portion 11 of the display circuit.

According to the present invention, the inspection circuit 3 described above can inspect the memory array 9 and the input portion 11 of the display circuit. Further, at the time of normal operation, for example, display based on the data in the memory array 9 can be performed.

### EXAMPLE 7

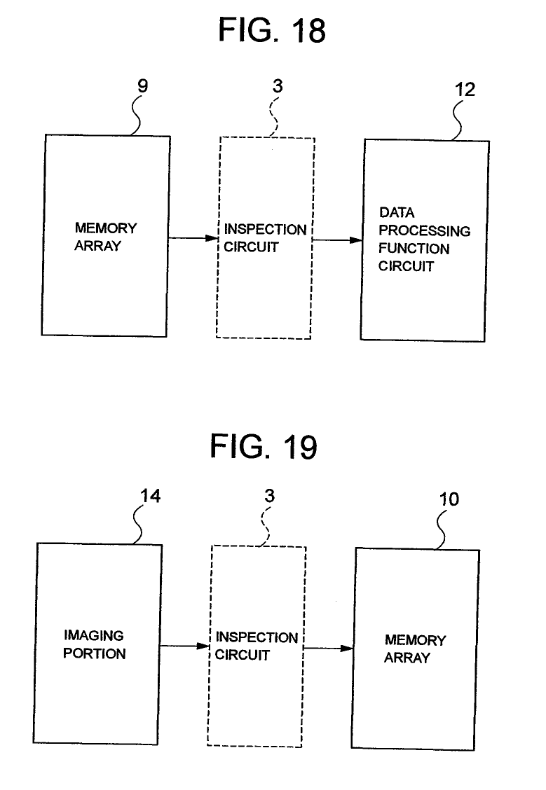

FIG. 18 is a schematic view illustrating a configuration of a seventh example of an inspection system according to the present invention. Referring to FIG. 18, the seventh example of the present invention is the device that the first circuit 1 is a memory array 9 and the second circuit 2 is a data processing function circuit 12. In this configuration, data is transferred from the memory array 9 to the data processing function circuit 12.

According to the present invention, the inspection circuit 3 described above can inspect the memory array 9 and the data processing function circuit 12. Further, at the time of normal operation, for example, data processing using the data in the memory array 9 can be performed by the data processing function circuit 12.

### EXAMPLE 8

FIG. 19 is a schematic view illustrating a configuration of an eighth example of an inspection system according to the present invention. Referring to FIG. 19, the eighth example of the present invention is the device that the first circuit 1 is an imaging portion 14 and the second circuit 2 is a memory array 10. This configuration is used when data obtained by the imaging portion 14 may be transferred to the memory array 10.

According to the present invention, the inspection circuit 3 described above can inspect the imaging portion 14 and the memory array 10. Further, at the time of normal operation, for example, image data taken up by the imaging portion 14 can be stored in the memory array 10.

### EXAMPLE 9

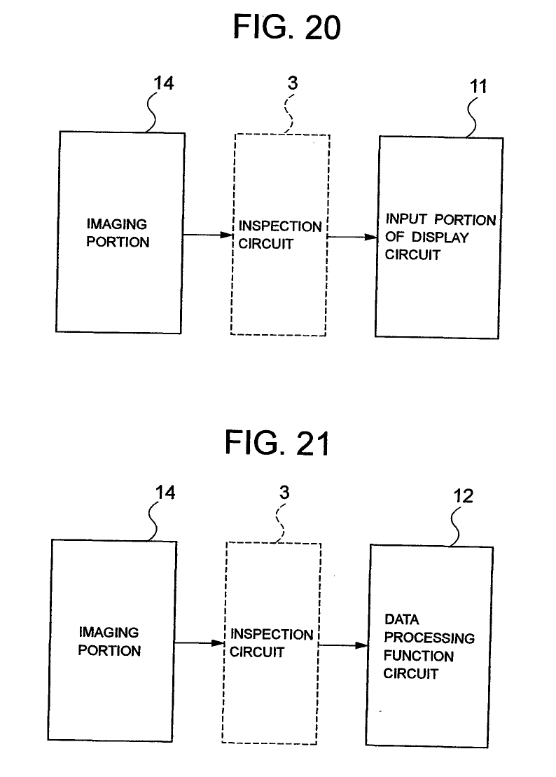

FIG. 20 is a schematic view illustrating a configuration of a ninth example of an inspection system according to the present invention. Referring to FIG. 20, the ninth example of the present invention is the device that the first circuit 1 is an imaging portion 14 and the second circuit 2 is an input portion 11 of a display circuit. This configuration is used when data may be transferred from the imaging portion 14 to the input portion 11 of the display circuit.

According to the present invention, the inspection circuit 3 described above can inspect the imaging portion 14 and the input portion 11 of the display circuit. Further, at the time of normal operation, for example, display based on image data taken up by the imaging portion 14 can be performed.

### EXAMPLE 10

FIG. 21 is a schematic view illustrating a configuration of a tenth example of an inspection system according to the present invention. Referring to FIG. 21, the tenth example of the present invention is the device that the first circuit 1 is an imaging portion 14 and the second circuit 2 is a data processing function circuit 12. In this configuration, data is transferred from the imaging portion 14 to the data processing function circuit 12.

According to the present invention, the inspection circuit 3 described above can inspect the imaging portion 14 and the data processing function circuit 12. Further, at the time of normal operation, for example, data processing can be performed by the data processing function circuit 12, using image data taken up by the imaging portion 14.

### EXAMPLE 11

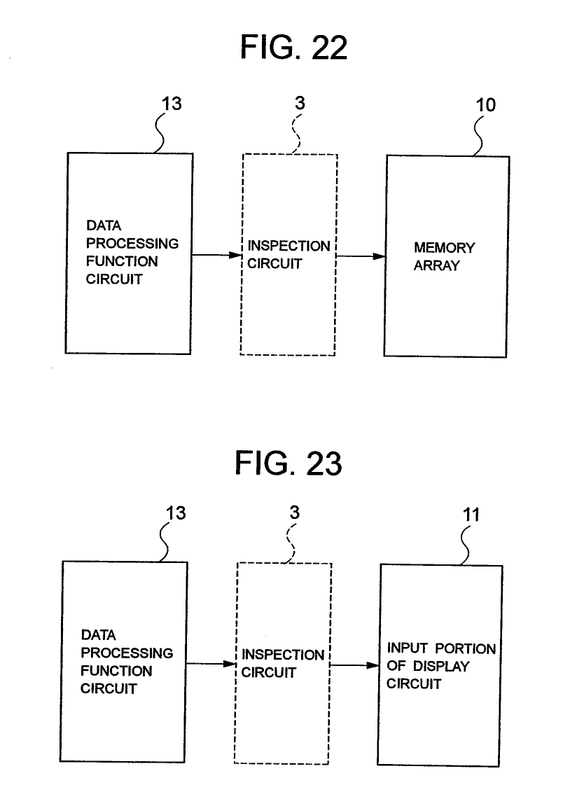

FIG. 22 is a schematic view illustrating a configuration of an eleventh example of an inspection system according to the present invention. Referring to FIG. 22, the eleventh example of the present invention is the device that the first circuit 1 is a data processing function circuit 13 and the second circuit 2 is a memory array 10. This configuration is used when data processed by the data processing function circuit 13 may be transferred to the memory array 10.

According to the present invention, the inspection circuit 3 described above can inspect the data processing function circuit 13 and the memory array 10. Further, at the time of normal operation, for example, data processed by the data processing function circuit 13 can be stored in the memory array 10.

### EXAMPLE 12

FIG. 23 is a schematic view illustrating a configuration of a twelfth example of an inspection system according to the present invention. Referring to FIG. 23, the twelfth example of the present invention is the device that the first circuit 1 is a data processing function circuit 13 and the second circuit 2 is an input portion 11 of a display circuit. This configuration is used when data may be transferred from the data processing function circuit 13 to the input portion 11 of the display circuit.

According to the present invention, the inspection circuit 3 described above can inspect the data processing function circuit 13 and the input portion 11 of the display circuit. Further, at the time of normal operation, for example, display based on data processed by the data processing function circuit 13 can be performed.

### EXAMPLE 13

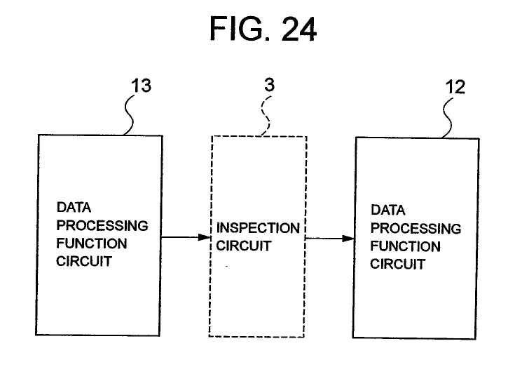

FIG. 24 is a schematic view illustrating a configuration of a thirteenth example of an inspection system according to the present invention. Referring to FIG. 24, the thirteenth example of the present invention is the device that the first circuit 1 is a data processing function circuit 13 and the second circuit 2 is a data processing function circuit 12. This configuration is used when data is transferred between the data processing function circuit 13 and the data processing function circuit 12, alternately when data may be transferred from one of the data processing function circuits to the other of the data processing function circuits.

According to the present invention, the inspection circuit 3 described above can inspect the data processing function circuit 12, 13. Further, at the time of normal operation, for example, data processing can be performed by the next data processing function circuit 12, using data processed by the first data processing function circuit 13.

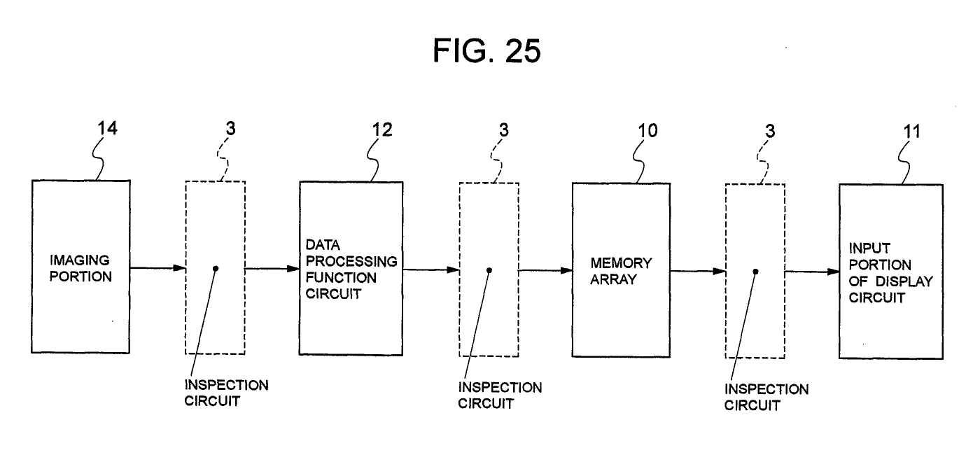

The fifth to thirteenth examples of the present invention may be also combined with each other. For example, the inspection circuit may be also disposed one-by-one between each of circuits as shown in FIG. 25. In this example, the image data taken up by the imaging portion 14 is processed by the data processing function circuit 12, the processed data is stored in the array memory 10, and the stored data is input into the input portion 11 of the display circuit to be displayed. Since the inspection circuit 3 of the present invention is disposed between each of the circuits, all the circuit blocks can be inspected.

For example, the inspection circuit 3 between the data processing function circuit 12 and the memory array 10 can inspect an output of the data processing function circuit 12 and input an inspection signal into the memory array 10. Using the inspection signal input into the memory array 10, the inspection circuit 3 between the memory array 10 and the input portion 11 of the display circuit can inspect an output of the memory array 10. Combination of these examples can be freely adapted to be any combination.

### EXAMPLE 14

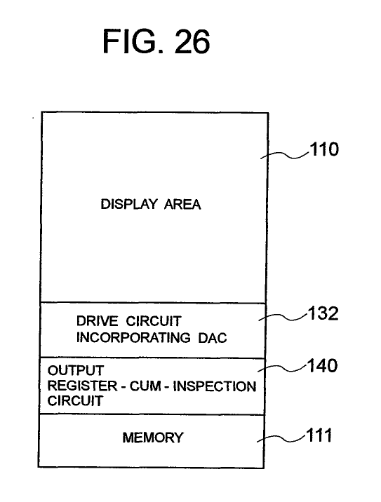

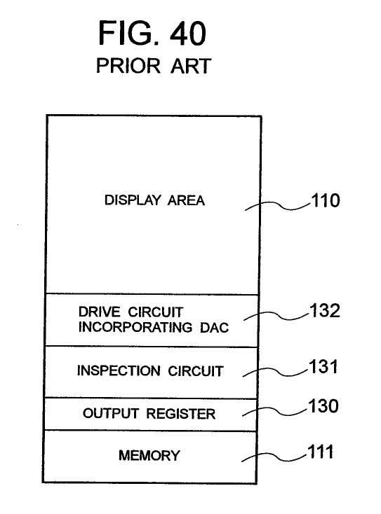

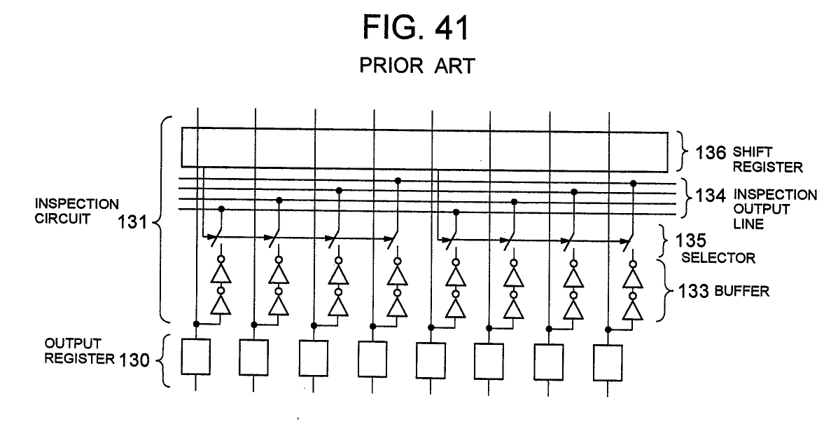

FIG. 26 is a schematic view illustrating a configuration of a fourteenth example of an inspection system according to the present invention. Referring to FIG. 26, the fourteenth example of the present invention is one example of a configuration for a display incorporating a memory. This is an inspection system of the present invention compared to an inspection system of the display incorporating a memory shown in FIG. 40 described above.

Referring FIG. 26, an output of a memory 111 is held temporarily in an output register-cum-inspection circuit 140. The output of the memory 111 passes through the output register-cum-inspection circuit 140 without its data state change at the time of normal operation. The data which has passed through the output register-cum-inspection circuit 140 is transferred in a display area 110 by a drive circuit incorporating a DAC 132. On the one hand, on inspection, the output of the memory 111 is output for inspection through the output register-cum-inspection circuit 140.

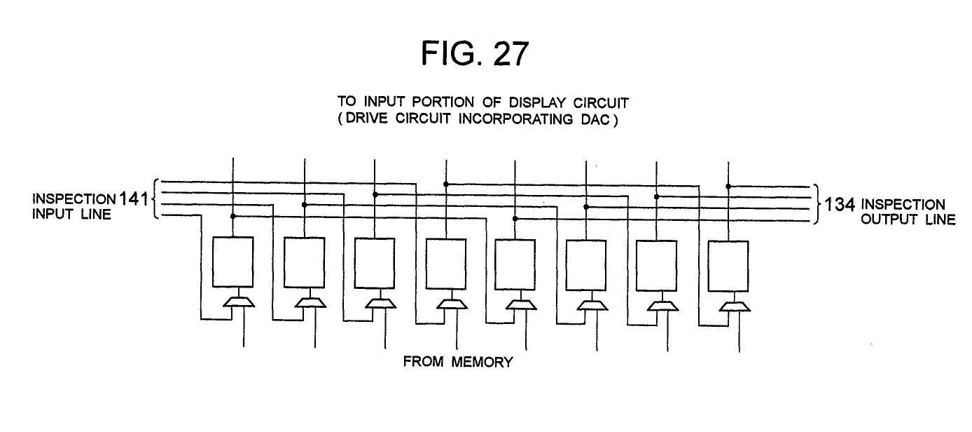

FIG. 27 shows an example of a circuit of the output register-cum-inspection circuit 140 configured as shown in FIG. 26. The output register-cum-inspection circuit 140 is configured using many flip-flops etc., and an output thereof is connected to the side of the drive circuit incorporating a DAC. Further, the output of the output register-cum-inspection circuit 140 branches to enter a multiplexer connected to the next stage flip-flop etc.

An input of the multiplexer is selected by a signal such as an inspection enable (not shown). When the multiplexer is selected to connect between the flip-flops, a shift register is formed. In the example shown in FIG. 27, the output of the shift register is selected by 4-bits and output into 4-bit inspection output line 134.

On the other hand, the multiplexer of the flip-flop without a previous stage is connected to an output of the memory and an inspection input line 141. When an input from the inspection input line 141 is selected, the inspection signal is transferred in series through the shift register and input into the drive circuit incorporating a DAC.

The circuit shown in FIG. 27 is configured, for example, by using the D flip-flop of FIG. 8. When the D flip-flop of FIG. 9 is used as a flip-flop, also the clock may be switched. In this case, at the time of normal operation, the inspection circuit functions as the output register, and when the output of the memory is latched to be transferred to the drive circuit incorporating a DAC (corresponding to FIG. 5), an inspection enable signal is turned off. At this time, according to a clock to latch the output of the memory, the output of the memory is latched in series.

On the one hand, on inspection of the output of the memory, the inspection circuit functions as the shift register (corresponding to FIG. 6). At this time, the inspection enable signal is turned on. By using a clock to inspect the memory, the output of the memory is read out externally in series through the shift register. Further, also when the inspection signal is input into the drive circuit incorporating a DAC (corresponding to FIG. 7), the inspection enable signal is turned on. By using either the same clock as that to inspect the memory or a dedicated clock to inspect the drive circuit incorporating a DAC, the inspection input signal is input in series through the shift register.

Increase in load capacitance causes signal rising to be slow, as well known. In the conventional configuration of FIG. 40, an inspection output line is very long. Further, parasitic capacitance such as cross capacitance etc. is produced among the inspection output line, an output line of the output register, a line to switch a selector and an output line of the selector.

Further, parasitic capacitance such as cross capacitance etc. is also produced between the output line of the output register and the shift register. Accordingly, it is necessary for a buffer to be large-size, which is disposed before the selector required to drive the entire inspection output line. Further, large parasitic capacitance causes signal rising to be slow, resulting in a larger size of buffers for all signals.

On the one hand, in the configuration of the present invention shown in FIG. 27, parasitic capacitance is reduced. Further, since the shift register directly pass on the inspection data, different from FIG. 40, a final length of the inspection output line is short and parasitic capacitance etc. is scarcely present. As the result, according to the present invention, the circuit itself can be simplified to reduce a circuit area and a size of the buffer can be reduced, resulting in a largely reduced circuit area.

### EXAMPLE 15

When estimating the inspection output, as required, compression of the inspection result can decrease largely a cost of inspection. This method may not be used when sequential inspection of all output is essential, but it may be very effectively used when the compression result may be an alternative to inspection, or when the scope of target for inspection of all output is limited by using, in conjunction with inspection of all output, the compression inspection method in an initial test.

A configuration to which this compression function of the inspection output is added will be shown as a fifteenth example of the present invention. For the compression of the inspection output, various methods may be used. Here, an example using a MISR (multiple input signature register) which is a pattern compression circuit will be described.

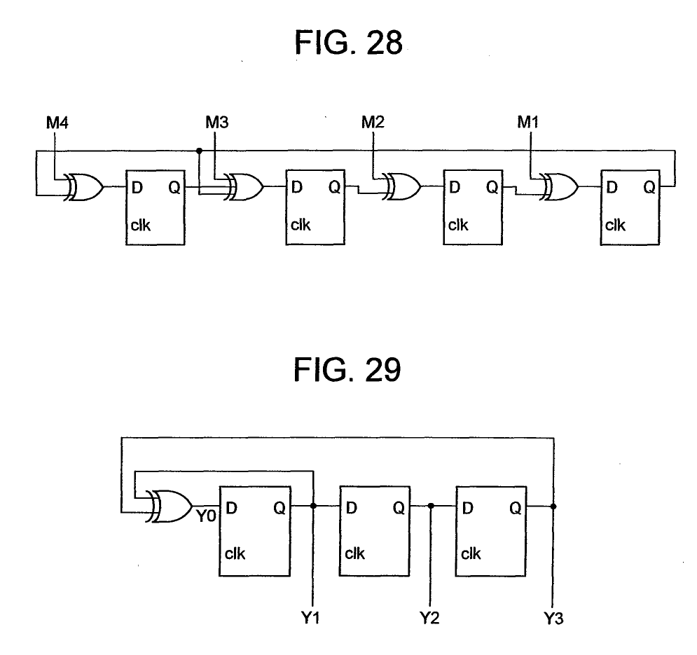

FIG. 28 is a schematic view illustrating a configuration of the fifteenth example of an inspection system according to the present invention. FIG. 28 shows a configuration of an example of the MISR. Referring to FIG. 28, the example of the MISR includes a flip-flop and an EXOR (exclusive OR). This circuit compresses a bit sequence of N bits (N: positive integer, 4 as one example in FIG. 28) which has been input, to an N-degree bit sequence state called “signature”. When a different bit sequence is input, then a different signature is inevitably produced except accidental coincidence produced with a probability of ½N.

It is possible to determine whether an item is good or not by analyzing whether a signature coincident with input data is output or not. Using a compression circuit allows the number of output signal line to be reduced, resulting in a low cost of inspection. Further, since determination whether the item is good or not can be made only by analyzing whether the signature output is coincident with the input data or not, a size of a determination circuit can be reduced.

To connect a semiconductor device of the present invention to an inspection device such as an external LSI tester (logic tester, memory tester, mixed signal tester etc.) or an array tester etc., there can be various methods. For example, there may be used a test bus method that a test bus is provided separately from a system bus and an interface signal in each of inspection blocks in the semiconductor device is accessed through the test bus.

Further, there may be also used a multiplex method (pulling out method) that an external pin is commoditized by multiplexing an interface signal in each of the inspection blocks in the semiconductor device and a signal at the time of normal operation, and then signaling from the external pin is controlled by a test control signal. Further, there may be also used a core test method etc. that an inspection access structure is provided, and on inspection, each of the inspection blocks is accessed through the inspection access structure. When the core test method is used, an interface circuit called “wrapper” is provided in each of the inspection blocks and accordingly inspection routine and the inspection access structure for each of the inspection blocks can be effectively developed.

### EXAMPLE 16

Further, a random pattern may be also used as the inspection input signal. As for a generator of the random pattern, for example, a LFSR (linear feedback shift register) may be used. This LFSR is a generator circuit of M-Sequence (maximum length code) pseudo random number. The M-Sequence pseudo random number has the following features.

First, it has a feature of similarity to true random number at the two following points. The first point is that a ratio of “0” and “1” is approximately equal (to be exact, the number of “0” is less by 1 than that of “1”). The second point is that “run” in which one of “1” and “0” is generated sequentially has the same feature as the true random number (a frequency of “run” with a length of m is twice as high as that of “run” with a length of m+1).

On the one hand, in circuit manufacturing, it has a feature that when hardware is used to implement, a circuit configuration is simple. That is, the circuit may be realizes by forming an X-bit shift register and forming a feedback tap through which a bit corresponding to its characteristic polynomial is fed back by an EXOR.

FIG. 29 is a schematic view illustrating a configuration of a sixteenth example of an inspection system according to the present invention. FIG. 29 illustrates a configuration of an example of a three-stage LFSR circuit. According to a simple configuration as shown in FIG. 29, the pseudo random number having characteristics near the true random number may be provided. Using the pseudo random number output by this LFSR as the inspection input signal allows inspection of a circuit to be inspected to be performed under various conditions (various bit states).

In addition, when an output from the LFSR is input in series into a shift register configured to be parallel, there may occur a state that a logic value between flip-lops called “FF logic value correlation” takes always the same value, and therefore a detection rate of failure may decrease. Inserting a phase shifter connecting between each bit of the LFSR by the EXOR can eliminate the correlation, resulting in a higher detection rate.

### EXAMPLE 17

In a seventeenth example, what is called “logic BIST (built-in self test)” is formed. That is, the LFSR described above is used as a TPG (test pattern generator), and further a circuit called “ORA (output response analyzer)” or “TRA (test response analyzer)” is embedded, which determines failure based on the compression result by the MISR described above.

In the present invention, the TPG is used for inputting for inspection of the first circuit. The inspection input from the TPG is input into the first circuit, its output is output by the inspection circuit of the present invention, and its output is input into the MISR to compress and determine whether good or not by a determination circuit. As shown in FIG. 25, when a plurality of the examples of the present invention are combined, the inspection signal from the TPG may be used as the inspection input signal of the inspection circuit of the present invention.

Owing to the logic BIST configured as described above, the number of external pin is reduced. Further, a data transfer rate from and to the outside may be made lower. As the result, a configuration of the external inspection device may be also simplified, reducing a cost of inspection largely.

### EXAMPLE 18

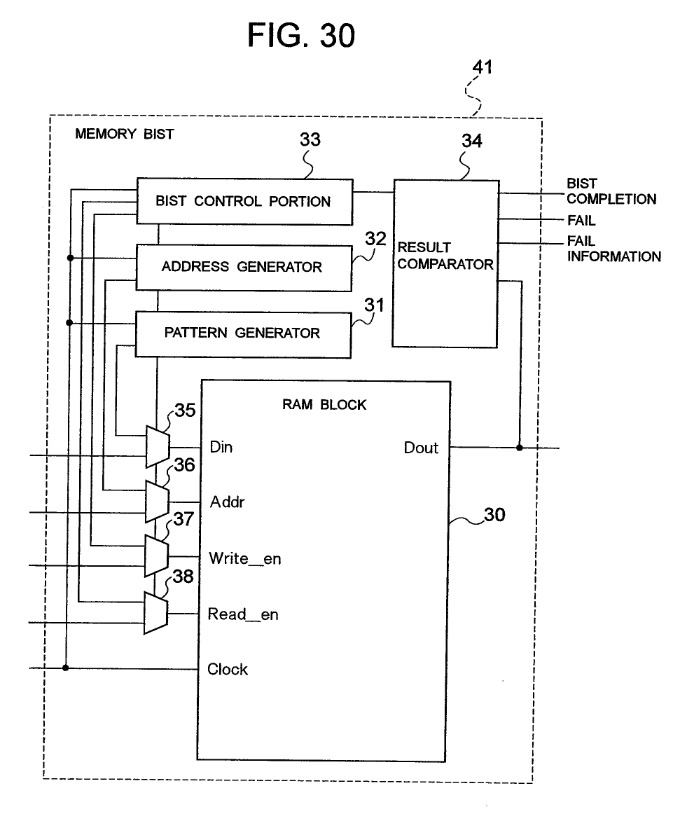

On memory inspection, the method of the present invention that all data is read out externally and a method called “memory BIST” can be used together, resulting in more reliable inspection. This is an eighteenth example of the present invention. FIG. 30 is a schematic view illustrating a configuration of an example of the memory BIST.

Referring to FIG. 30, a memory BIST 41 includes a RAM (random access memory) 30, a pattern generator 31, an address generator 32, a BIST control portion 33, a result comparator 34 and a selector 35 to 38.

In the memory BIST 41, data created by the pattern generator 31 and the address generator 32 is input into a data input (Din) and an address input (Addr) of a RAM block 30, respectively. The selector 35 to 38 disposed before the RAM block 30 selects a signal. Operation of the BIST is controlled through the BIST control portion 33. An output from the RAM block 30 is compared with an expected value by the result comparator 34, and only pass/fail result obtained from the comparison is output. In FIG. 30, for the case where analysis is required, a configuration in which fail information can be read out is shown.

In the present invention, along with this memory BIST 41, an inspection circuit to read our all data externally is provided. The memory BIST 41 initially estimates and finds an abnormal point, and subsequently a faulty portion can be analyzed in detail by reading out all data externally through the inspection circuit of the present invention. This method can reduce a cost of inspection largely.

### EXAMPLE 19

On the one hand, BIST is also configured for an analog circuit, and thus a cost of an external inspection device can be reduced. However, analog BIST is more affected by change in parameter of semiconductor process, compared to the logic BIST.

That is, due to large change in analog performance of a BIST circuit itself, the BIST circuit cannot work as the inspection circuit. For measures against this, there may be considered an approach that a complete BIST circuit is not configured, but a simplified BIST circuit is formed, and then final inspection is carried out by using an external inspection device.

For example, there may be considered a method that an output frequency is lowered, thereby reducing a cost of an external estimation device. As for a nineteenth example of the present invention, there may be quoted a configuration of BIST for an analog circuit, which drops an output frequency by using a built-in clocked comparator.

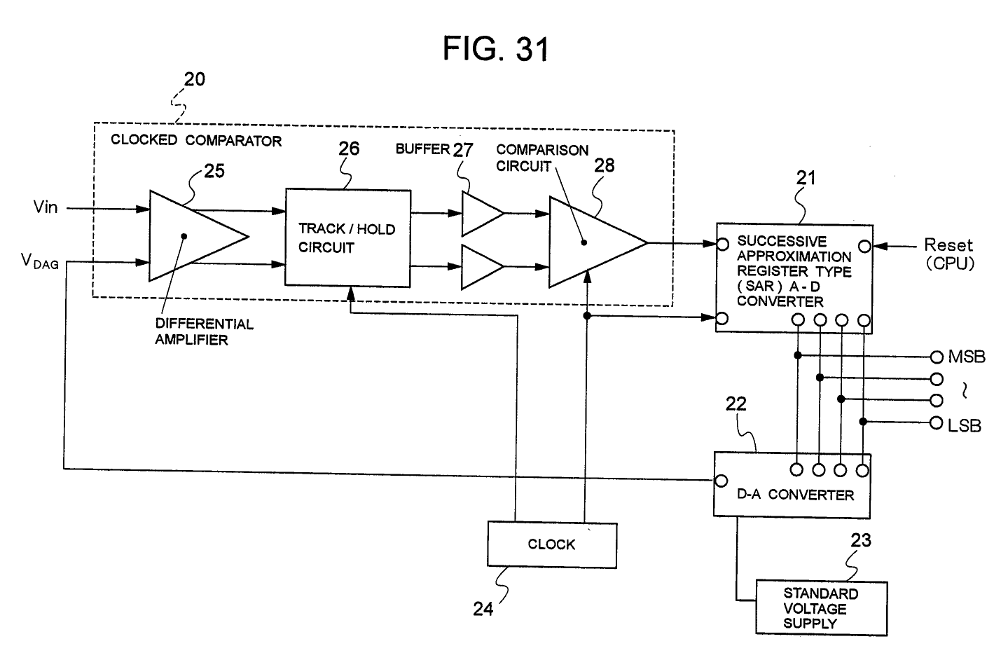

FIG. 31 is a schematic view illustrating a configuration of an example of the BIST circuit of the nineteenth example. In the configuration in FIG. 31, only the clocked comparator 20 is embedded in the BIST circuit, and an SAR (successive approximation register type) A-D converter 21, a D-A converter 22, a standard voltage supply 23 and a clock 24 are provided on the inspection device side.

In the built-in clocked comparator 20, a differential amplifier 25 compares a voltage to be measured Vin in an internal circuit with a high-accuracy DC voltage VDAC supplied from the inspection device. Then, an output of the differential amplifier 25 is under-sampled by a track/hold circuit 26 to be converted into a lowered-frequency signal. The signal having its frequency converted to be lower passes through a buffer 27 and a comparison circuit 28 to the SAR A-D converter 21, and there it is converted into a digital signal in sequence from MSB finally to LSB. The lowered frequency may allow a high-accuracy A-D converter to be used for the SAR A-D converter 21.

The SAR A-D converter 21 includes usually a comparator, an n-bit D-A converter, a SAR (successive approximation register) and a control portion. Performance of the D-A converter constituting the SAR A-D converter 21 has large decisive influence on performance as A-D converter. Especially, if zero-crossing distortion is present in the D-A converter, also an output of the SAR A-D converter 21 may come to be undesirable.

According to the present invention, since the signal to be estimated by the inspection device is converted into the lowered-frequency signal, a D-A converter having low zero-crossing distortion can be used for the D-A converter in the SAR A-D converter 21, providing desired inspection accuracy.

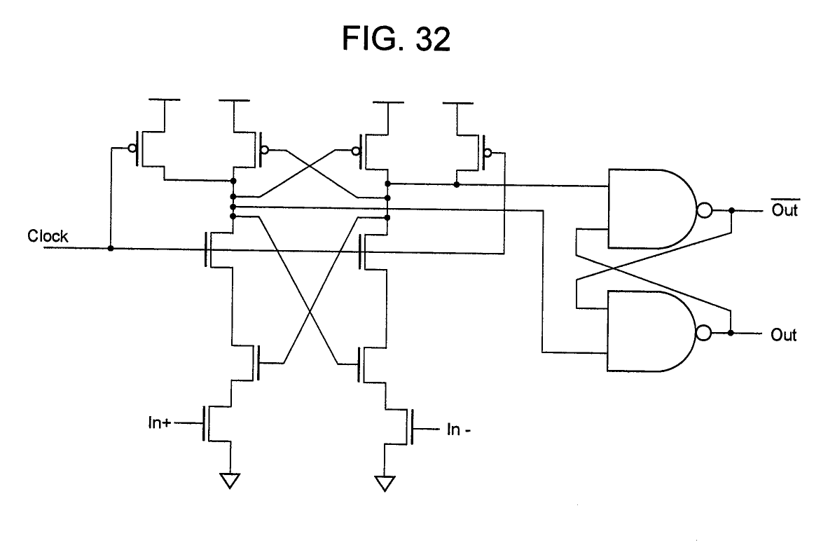

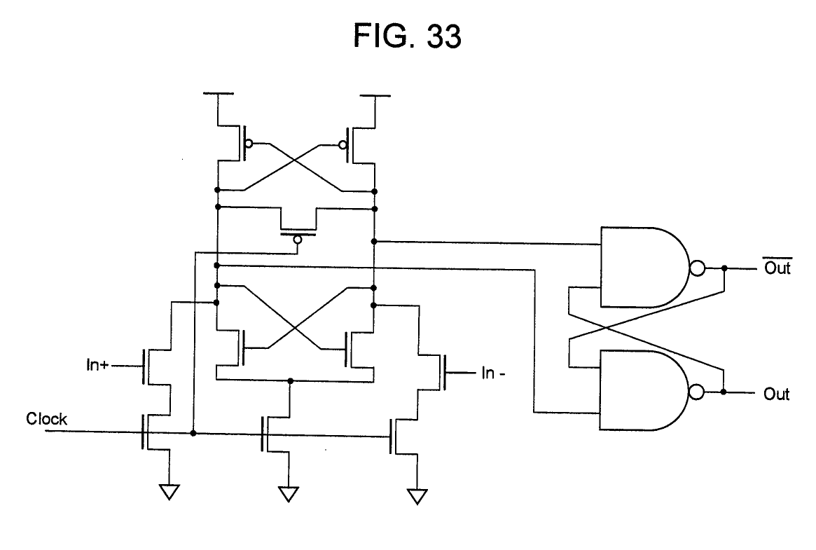

As for the clocked comparator used in this example, for exemption, a configuration shown in FIG. 32 or FIG. 33 may be also used. The clocked comparator shown in FIGS. 32 and 33 uses a latch formed by an inverter for a basic configuration. To operate the clocked comparator in synchronization with a clock and reduce power consumption, an NMOS switch controlled by the clock is added.

In addition, to erase a memory in the comparator before new comparison, that is, to make the comparator in equilibrium, a PMOS switch is added. When the clock turns to “H” (high), the PMOS switch is turned to off, the NMOS switch is turned to on, and the inverter is latched into a stable state.

According to the present invention, since the number of pin may be reduced and the number of element to be inspected at the same time may be increased, a test cost can be reduced.

In this example, the examples in which the BIST is configured are mainly shown, but BOST (built-out self test) may be used, in which a functional portion for self test is provided on an interface board in the inspection device.

### EXAMPLE 20

A twentieth example is the example in which the examples 1 to 19 described above are brought into more specific form. In this example, a TFT array of polysilicon (polycrystalline silicon, poly-Si) was made. Specifically, after an oxide silicon film was formed on a glass substrate, amorphous silicon was grown.

Next, an excimer laser was used to anneal the amorphous silicon, providing polysilicon, and further an oxide silicon film of 100 Å (10 nm) was grown. After patterning, a source region and a drain region were formed by patterning a photoresist and doping phosphorus ions.

Further, after an oxide silicon film of 900 Å (90 nm) was grown, microcrystalline silicon (μ-c-Si) and tungsten silicide (WSi) were grown to be patterned in shape of gate.

After an oxide silicon film and a silicon nitride film were grown in succession, a hole for a contact was made, and aluminum and titanium were formed by sputtering and patterned. A silicon nitride film was formed, a hole for a contact was made, and ITO (indium tin oxide) providing a transparent electrode for a pixel electrode was formed and patterned.

As described above, a TFT pixel switch of planar type is formed to provide the TFT array. A peripheral circuit was formed by making, along with an n-channel TFT similar to the pixel switch, a TFT adapted to be p-channel by doping, though in an approximately similar process for the n-channel TFT.

A DRAM (dynamic random access memory) made of a TFT as data storing means was formed. One memory cell of the DRAM was formed of one transistor and one capacitor. This memory cell is connected to a bit line and a word line. A memory cell array composed of a pair of the bit lines and the memory cell was formed by arranging such a memory cell alternately between the two bit lines. Details of a circuit on a TFT substrate will be described below.

Further, a patterned pillar of 4 μm was formed on the TFT substrate, to use as a spacer to keep a cell gap and at the same time to provide resistance to impact force. Further, UV cure seal material was applied outside a pixel region on an opposing substrate on which a transparent electrode was patterned in the pixel region. Liquid crystal was dropped by a dispenser, the TFT substrate and the opposing substrate were joined, and the seal portion was irradiated with ultraviolet radiation to adhere. Liquid crystal material was nematic liquid crystal and made to be of twist nematic (TN) type by adding chiral material and matching to the rubbing direction.

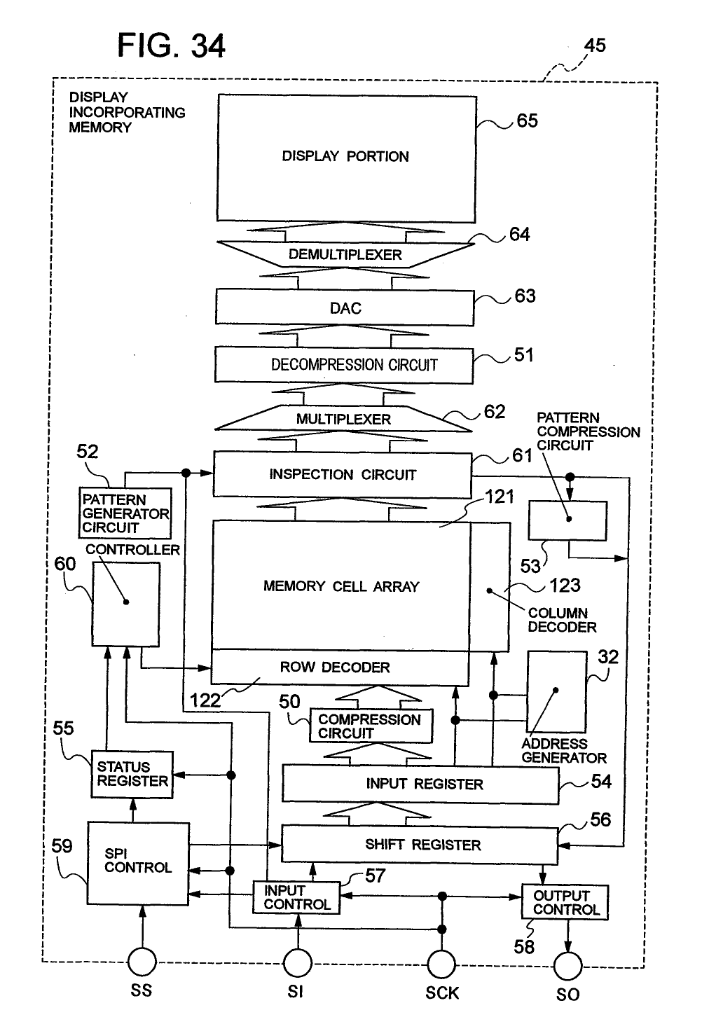

FIG. 34 is a schematic view illustrating a configuration of an example of a circuit on the TFT substrate. In this example, the present invention is applied to one example of a display incorporating a memory. Referring to FIG. 34, the one example of the display incorporating a memory 45 includes a display portion 65, a demultiplexer 64, a DAC 63, a decompression circuit 51, a multiplexer 62, an inspection circuit 61, a pattern generator circuit 52, a controller 60, a status register 55, a SPI (serial-parallel interface) control portion 59, an input control portion 57, a memory cell array 121, a row decoder 122, a column decoder 123, an address generator 32, a compression circuit 50, an input register 54, a shift register 56 and an output control portion 58.

Further, the one example of the display incorporating a memory 45 has a built-in SPI on the TFT substrate to communicate with an external control portion (CPU or MPU) through a serial interface. The SPI uses a 4-line system. Here, a signal used may include a serial input SI, a serial output SO, a serial clock SCK and a slave select input SS.

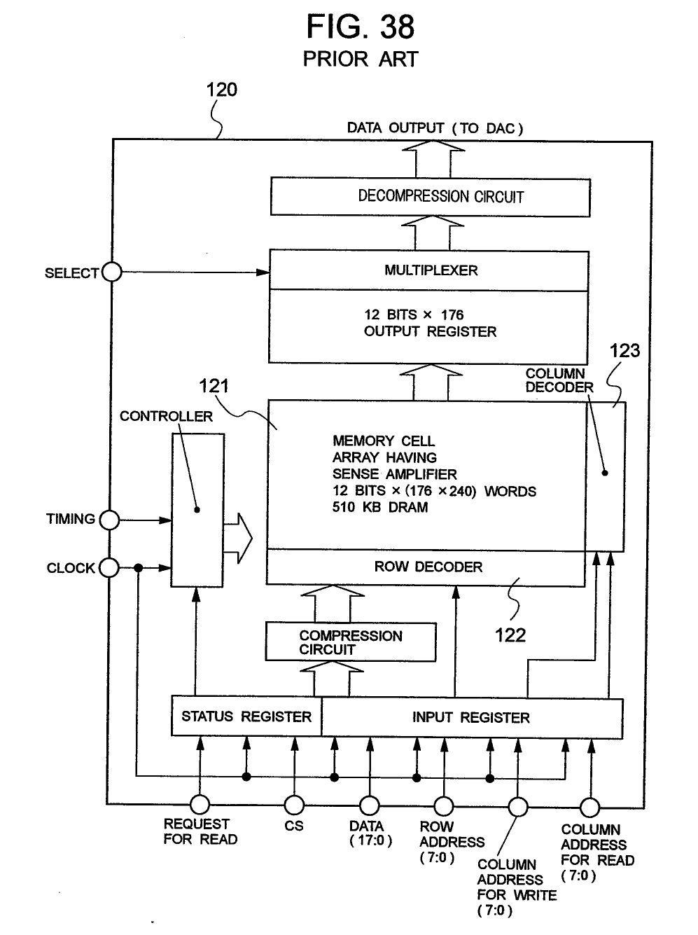

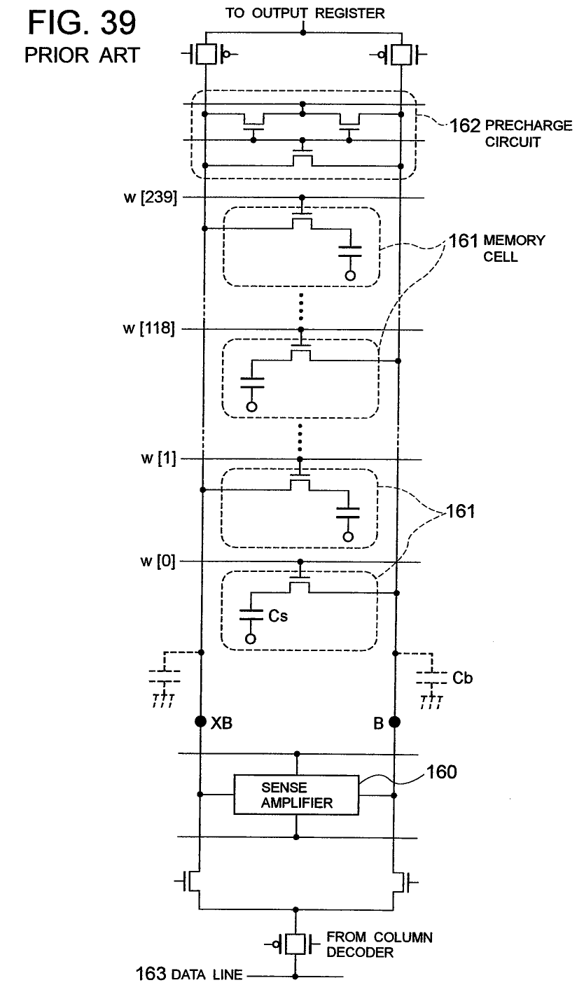

The SPI of the present invention, in addition to the shift register 56, the input control portion 57, the output control portion 58 and the SPI control portion 59, includes the input register 54 and the status register 55. A serial signal input by the input control portion 57 is converted from serial to parallel form by the shift register 56. The parallel data is held by the input register 54 and dealt with as data to be used for address control of memory or written into the memory cell by the SPI control portion 59, the status register 55 and the controller 60. Then, for subsequent operation, the SPI operates similarly to the frame memory on the conventional glass substrate shown in FIG. 38 up to operation of writing into and reading out a memory array 121.

Data read out from the memory array 121 is input into the multiplexer 62 through the inspection circuit 61 of the present invention at normal operation. Image data in an output of the multiplexer 62 is expanded into data form having the original number of bit by the decompression circuit 51. Next, the data is converted into analog data by the DAC circuit 63, and then, it is supplied to the display portion 65 through the demultiplexer 64 to realize image display.

When the memory which is the first circuit is inspected, the inspection circuit 61 used for this example can be one selected from a system that all output is read out in form of serial data, and a system that after all output is converted into compressed data by the pattern compression circuit 53, the data is read out externally (a select switch is not shown). These inspection outputs can be read out externally through the output control portion 58 of the SPI. In FIG. 34, the data is passed through the shift register 56 before it is read out by the output control portion 58, but the shift register 56 may not be necessary, or an output buffer may be separately provided.

Further, when the inspection signal is input into the input portion of the display portion which is the second circuit, the inspection circuit 61 used for this example can be one selected from a system that serial data applied externally is used as the inspection signal and a system that the pseudo random number created by the pattern generator circuit 52 is used as the inspection signal (a select switch is not shown). The inspection signal input through the inspection circuit 61 is passed on finally to the display portion to display as screen image, and it is possible to determine from the screen image whether failure is present or not in circuits following after the inspection circuit 61.

In this example, in an early stage of inspection process, the memory and the display portion can be inspected by using the pattern generator circuit 52 and the pattern compression circuit 53. Thus, a cost of inspection can be reduced largely. For a product for which a detection rate of failure is required higher than that in the early stage of inspection process, a product in which a phenomenon difficult to determine to be faulty or not is observed, or a product for which analysis of a cause of failure is necessary, an inspection method is used that serial data is directly input externally, and all data is directly output externally in form of serial data. This allows inspection to be performed under desired conditions, resulting in an improved detection rate of failure. Moreover, it may facilitate failure analysis.

In addition, in this example, because the serial interface is used for interface with an external control portion and a terminal of the serial interface is used for inputting and outputting for inspection, the number of terminal is not increased even due to addition of the inspection circuit. Further, because the inspection device may be simplified, a cost of inspection can be reduced largely.

It is possible to supply the inspection enable signal for this example by using several methods. For example, if normal operation is performed as a slave select input SS is in a selected state, there may be considered a method that the inspection enable signal is created by the SPI control portion 59 when the slave select input SS is in an unselected state. This method may allow supplying the inspection enable signal without increase in the number of an input and output terminal.

However, in case of a usual product, before shipping after inspection, it is necessary to cut connection to the inspection enable signal by a laser cutter etc. The reason is that if the inspection enable signal remains connected, when the slave select signal SS is brought into the unselected state at normal operation, operation moves to an inspection mode, and therefore power may be consumed extra (but, there is not a problem when also power is not supplied).

In this example, another method was used that a dedicated terminal of the inspection enable signal was provided. In this method, the number of terminal may increase, but it is not necessary to cut connection to the inspection enable signal. Further, when a product after shipping is sent back because of its fault, this method also has an advantage that failure analysis is possible.

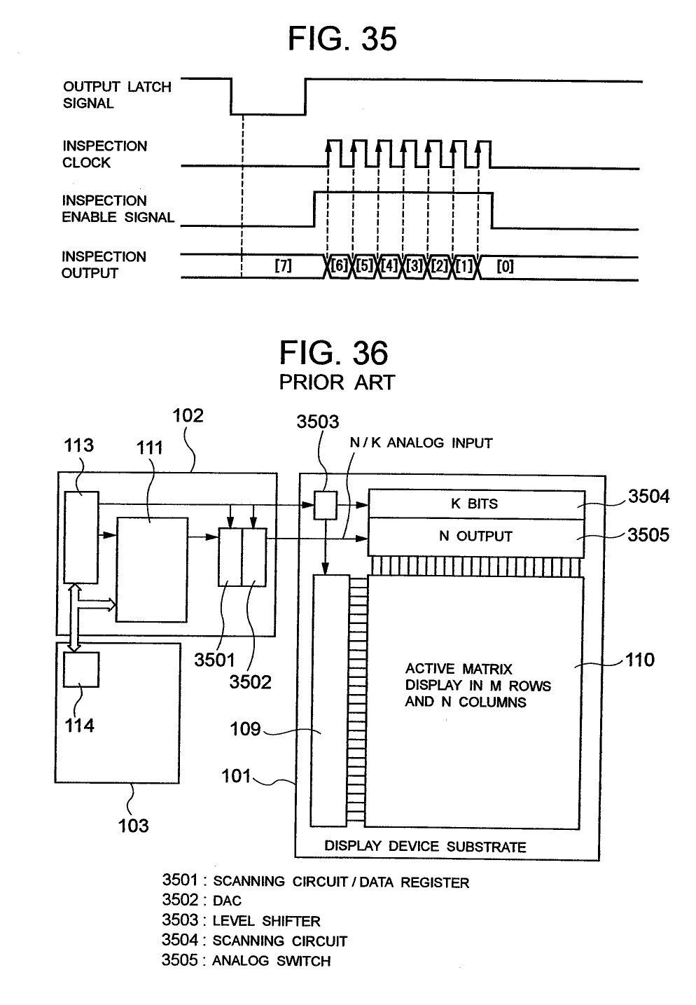

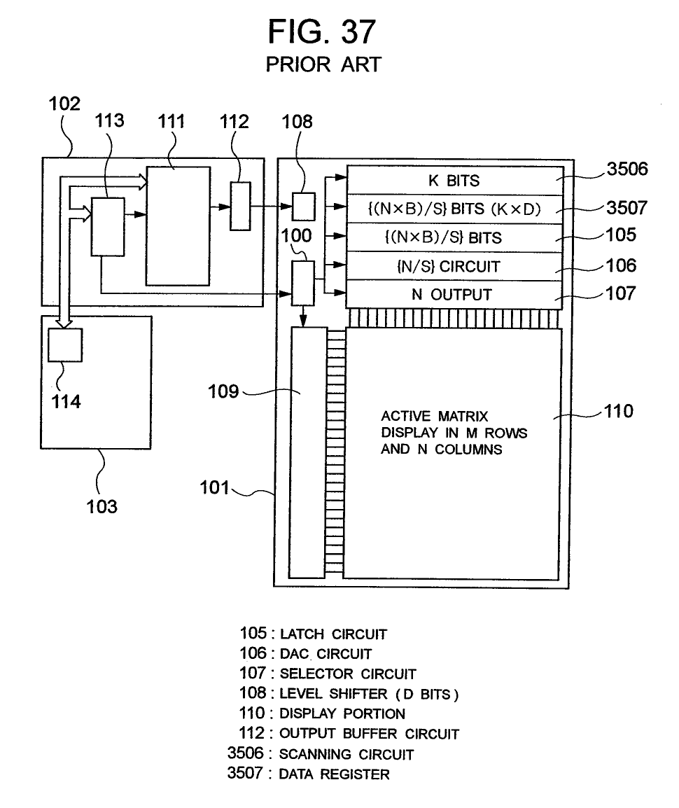

FIG. 35 is a schematic view illustrating an example of a timing chart for this example. Here, an example in which an 8-bit shift register is configured is shown. Further, a timing chart is shown when the memory which is the first circuit is inspected.

First, in the circuit configuration corresponding to FIG. 5, the output latch signal (a clock for latch etc.) is input, and accordingly data of the memory is latched. At this time, data of the final stage of the memory (denoted by the inspection output “7”) from the flip-flop corresponding to the final bit in the shift register has been output to the inspection output portion.

Next, the inspection circuit is changed to the shift register configuration as shown in FIG. 6 due to the inspection enable signal. Here, when an inspection clock is input, the memory output which has been latched is output on a bit basis in series. This situation is shown by illustrating the inspection output by “6”, “15”, . . . “11”, “0” in order. For 8-bit data, 7 clocks of the clock signal input allow all data to be output for inspection.

The reason is that, when configured as shown in FIG. 5 as described above, the inspection output “7” has been output. When the seventh clock is input, data of the inspection output “0” is output. In this example, because the data is shifted at a rising edge of the inspection clock, the inspection enable signal is selected before the first clock of the inspection clock rises, and it may be brought into an unselected state after the last clock of the inspection clock rises. As described above, according to the present invention, it is possible to output the inspection results by using a simple signal configuration.

What is claimed is:

1. An inspection circuit intervening between a first circuit and a second circuit, wherein
the inspection circuit comprises a signaling control portion of controlling signaling between the first circuit and the second circuit and an inspection output portion of inspecting at least one of the first circuit and the second circuit, and switches between the signaling control portion and the inspection output portion to use, and
each of the portions shares a part of a circuit to realize each portion with each other.

2. The inspection circuit according to claim 1, wherein the inspection output portion outputs externally an output of the first circuit.

3. The inspection circuit according to claim 1, wherein an input from the first circuit 1 to each of the portions in the inspection circuit is input by leading the output of the first circuit to branch.

4. The inspection circuit according to claim 1, wherein the inspection output portion inputs an inspection signal into the second circuit.

5. The inspection circuit according to claim 1, wherein the inspection output portion outputs externally an output of the first circuit and inputs an inspection signal into the second circuit.

6. The inspection circuit according to claim 1, wherein the shared circuit comprises a latch circuit.

7. The inspection circuit according to claim 6, wherein the latch circuit constituting the shared circuit is one of a flip-flop including a multiplexer, a two port flip-flop and a shift register latch.

8. The inspection circuit according to claim 1, comprising a pattern compression circuit for compressing data output by the inspection output portion.

9. The inspection circuit according to claim 1, comprising a pattern generator circuit for creating inspection data to be input into the inspection output portion.

10. The inspection circuit according to claim 1, wherein the shared circuit constitutes a shift register or functions as a shift register on inspection.

11. The inspection circuit according to claim 1, wherein the first circuit, the second circuit and the inspection circuit are disposed on the same substrate.

12. An inspection system, comprising the inspection circuit according to claim 1.

13. A semiconductor device, comprising the inspection circuit according to claim 1.

14. The semiconductor device according to claim 13, wherein
the first circuit is a memory array, and
the second circuit is a memory array.

15. The semiconductor device according to claim 13, wherein
the first circuit is a memory array, and
the second circuit is an input portion of a display circuit.

16. The semiconductor device according to claim 13, wherein
the first circuit is a memory array, and
the second circuit is a data processing function circuit.

17. The semiconductor device according to claim 13, wherein
the first circuit is an imaging portion, and
the second circuit is a memory array.

18. The semiconductor device according to claim 13, wherein
the first circuit is an imaging portion, and
the second circuit is an input portion of a display circuit.

19. The semiconductor device according to claim 13, wherein
the first circuit is an imaging portion, and
the second circuit is a data processing function circuit.

20. The semiconductor device according to claim 13, wherein
the first circuit is a data processing function circuit, and
the second circuit is a memory array.

21. The semiconductor device according to claim 13, wherein
the first circuit is a data processing function circuit, and
the second circuit is an input portion of a display circuit.

22. The semiconductor device according to claim 13, wherein
the first circuit is a data processing function circuit, and
the second circuit is a data processing function circuit.

23. The semiconductor device according to claim 13, comprising logic BIST (built-in self test) including a TPG (test pattern generator) and a TRA (test response analyzer).

24. The semiconductor device according to claim 13, comprising memory BIST (built-in self test) including a pattern generator, an address generator, a BIST control portion and a result comparator.

25. The semiconductor device according to claim 13, comprising analog BIST (built-in self test) including a clocked comparator.

26. The semiconductor device according to claim 13, wherein inputting and outputting for inspection are carried out by a serial interface.

27. A display device, included in the semiconductor device according to claim 13, wherein
the display device implements display function.

28. A method of inspecting a semiconductor device which transmits signals from a first circuit to a second circuit by a signaling circuit intervening between the first circuit and the second circuit, comprising:
inspecting an output of the first circuit by bringing the signaling between the first circuit and the second circuit to a halt and connecting an output of an output portion of the first circuit to an inspection output circuit which shares a part of a circuit with the signaling circuit.

29. A method of inspecting a semiconductor device which transmits signals from a first circuit to a second circuit by a signaling circuit intervening between the first circuit and the second circuit, comprising:
inputting an inspection signal into the second circuit by bringing the signaling between the first circuit and the second circuit to a halt and connecting an input of an input portion of the second circuit to an output of an inspection input circuit which shares a part of a circuit with the signaling circuit.

30. A method of inspecting a semiconductor device which transmits signals from a first circuit to a second circuit by a signaling circuit intervening between the first circuit and the second circuit, comprising:
inspecting an output of the first circuit by bringing the signaling between the first circuit and the second circuit to a halt and connecting an output of an output portion of the first circuit to an inspection output circuit which shares a part of a circuit with the signaling circuit, and
subsequently, inputting an inspection signal into the second circuit by disconnecting the output of the output portion of the first circuit from the inspection output circuit and connecting an input of an input portion of the second circuit to an output of an inspection input circuit which shares a part of a circuit with the signaling circuit.

31. A method of inspecting a semiconductor device which transmits signals from a first circuit to a second circuit by a signaling circuit intervening between the first circuit and the second circuit, comprising:
bringing the signaling between the first circuit and the second circuit to a halt and then inputting an inspection input signal which is to be output to the second circuit to an input portion of the inspection circuit,
outputting the inspection input signal from an output portion of the inspection circuit, and
then, comparing the inspection input signals input to and output from the inspection circuit,
thereby, operation of the inspection circuit itself is inspected.

32. An inspection system, comprising a first circuit, a second circuit and an inspection circuit intervening between the first circuit and the second circuit, wherein
the inspection circuit comprises a signaling control means of controlling signaling between the first circuit and the second circuit and an inspection output means of inspecting at least one of the first circuit and the second circuit, and switches between the signaling control means and the inspection output means to use, and
each of the means shares a part of a circuit to realize each means with each other.
